(19) United States
(12) Patent Application Publication
(10) Pub. No.: US 2024/0243588 A1
(43) Pub. Date: Jul. 18, 2024

(54) ELECTRICAL ENERGY STORAGE SYSTEMS WITH FLEXIBLE ELECTRICAL ARCHITECTURES

(71) Applicant: Dragonfly Energy Corp., Reno, NV (US)

(72) Inventors: Ryan Hopkins, Reno, NV (US); Andrew Warren, Reno, NV (US); Denis Phares, Reno, NV (US)

(73) Assignee: Dragonfly Energy Corp., Reno, NV (US)

(21) Appl. No.: 18/408,930

(22) Filed: Jan. 10, 2024

Related U.S. Application Data
(60) Provisional application No. 63/438,909, filed on Jan. 13, 2023.

(51) Int. Cl. H02J 7/00; H01M 10/46; H05K 1/18

(52) U.S. Cl. CPC H02J 7/0019; H01M 10/46; H02J 7/00032; H02J 7/0047; H02J 7/00711; H02J 7/00712; H05K 1/18; G06F 1/263; H05K 2201/10037; H05K 2201/10053

(57) ABSTRACT

Embodiments for configuring a battery system are described and may include a stack of commonly connected controller circuit boards configured to connect to any battery system to provide an expandable current/power capacity to meet flexible battery architectures. The controller circuit boards in the stack may be connected to each other. For example, multiple controller circuit boards may each include one or more commonly connected identical components. The common connections among the multiple controller circuit boards may enable the various components, e.g., switches, to be controlled together by common control signals from a processor. Embodiments related to battery systems with flexible connection architectures between adjacent sets of electrochemical cells are also disclosed. For example, multiple pairs of electrical terminals may be configured to be electrically connected to multiple electrical energy storage devices using a plurality of switches (e.g., FET switches) to provide a commanded configuration.

### RELATED APPLICATIONS

This application claims priority under 35 U.S.C. § 119(e) to U.S. Application Ser. No. 63/438,909, filed Jan. 13, 2023, and titled “ELECTRICAL ENERGY STORAGE SYSTEMS WITH FLEXIBLE ELECTRICAL ARCHITECTURES,” the content of which is incorporated herein by reference in its entirety for all purposes.

### FIELD

Disclosed embodiments are related to devices and methods for configuring and monitoring electrical energy storage systems including, for example, battery systems.

### BACKGROUND

A battery may include multiple sets of electrochemical cells physically secured in an enclosure, and electrically connected in a range of electrical configurations. For example, multiple sets of electrochemical cells may be connected in parallel to provide a higher current, or in series to increase output voltage. Further, multiple battery packs and systems may be provided to customers as modular components that may be assembled together in any number of different configurations with battery packs and/or cells located in series and/or parallel with one another depending on the desired application and overall battery configuration.

### SUMMARY

According to some embodiments, an apparatus for controlling a battery system is provided. The apparatus includes: a plurality of pairs of electrical terminals configured to be electrically connected to a plurality of electrical energy storage devices, where the plurality of pairs of electrical terminals include at least a first pair of electrical terminals and a second pair of electrical terminals. Each pair of electrical terminals include a positive terminal and a negative terminal. The apparatus also includes a plurality of switches configured to be independently controlled between an open configuration and a closed configuration. The plurality of switches include at least: a first switch electrically coupled to a positive terminal of the first pair of electrical terminals and a positive terminal of the second pair of electrical terminals; a second switch electrically coupled to a negative terminal of the first pair of electrical terminals and a negative terminal of the second pair of electrical terminals; and a third switch electrically coupled to the negative terminal of the first pair of electrical terminals and the positive terminal of the second pair of electrical terminals.

According to some embodiments, a method for controlling a battery system is provided. The method includes, by at least one processor: controlling one or more of a plurality of switches on a controller individually to connect one or more of a plurality of pairs of electrical terminals on the controller according to a commanded configuration. The plurality of pairs of electrical terminals are configured to be electrically connected to a plurality of electrical energy storage devices, where the plurality of pairs of electrical terminals include at least a first pair of electrical terminals and a second pair of electrical terminals. Each pair of electrical terminals include a positive terminal and a negative terminal. The plurality of switches are configured to be independently controlled between an open configuration and a closed configuration. The plurality of switches include at least: a first switch electrically coupled to a positive terminal of the first pair of electrical terminals and a positive terminal of the second pair of electrical terminals; a second switch electrically coupled to a negative terminal of the first pair of electrical terminals and a negative terminal of the second pair of electrical terminals; and a third switch electrically coupled to the negative terminal of the first pair of electrical terminals and the positive terminal of the second pair of electrical terminals.

According to some embodiments, an apparatus for controlling a battery system is provided. The apparatus includes: a plurality of controller circuit boards configured to connect with each other. Each of the plurality of controller circuit boards includes: a plurality of pairs of electrical terminals configured to be electrically connected to a plurality of electrical energy storage devices of the battery system; a plurality of switches electrically coupled to the plurality of pairs of electrical terminals; and a plurality of pins coupled to the plurality of switches to provide control signals to the plurality of switches. The plurality of switches are configured to control an electrical configuration of the plurality of electrical energy storage devices. The plurality of pins of the plurality of controller circuit boards are configured to be commonly connected.

According to some embodiments, a method for controlling a battery system is provided. The method includes, by at least one processor: controlling, with common control signals, a respective plurality of switches on each controller circuit board of a plurality of controller circuit boards connected with each other to connect one or more of a respective plurality of pairs of electrical terminals on the controller circuit board according to a commanded configuration. For each controller circuit board of the plurality of controller circuit boards: the plurality of pairs of electrical terminals are configured to be electrically connected to a plurality of electrical energy storage devices of the battery system; and the plurality of switches are electrically coupled to the plurality of pairs of electrical terminals. The plurality of switches are configured to control an electrical configuration of the plurality of electrical energy storage devices. The respective plurality of pairs of electrical terminals on each of the plurality of controller circuit boards are commonly connected. The respective plurality of switches on each of the plurality of controller circuit boards are also commonly connected.

It should be appreciated that the foregoing concepts, and additional concepts discussed below, may be arranged in any suitable combination, as the present disclosure is not limited in this respect. Further, other advantages and novel features of the present disclosure will become apparent from the following detailed description of various non-limiting embodiments when considered in conjunction with the accompanying figures.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1A is an illustrative diagram of a battery system in connection with a controller according to some embodiments;

FIG. 1B is an illustrative diagram a battery system in connection with multiple controllers according to some embodiments;

FIG. 1C is an illustrative diagram of multiple battery systems each connected with respective sets of controllers according to some embodiments;

FIG. 2A is an illustrative diagram of multiple sets of electrochemical cells which may be arranged in multiple groups in a battery system, according to some embodiments;

FIG. 2B is an illustrative diagram of multiple battery systems which are connected by bus bars, according to some embodiments;

FIG. 3A is an illustrative block diagram of multiple controller circuit boards of an exemplary implementation of multiple controllers as shown in FIG. 1B and FIG. 1C, according to some embodiments;

FIG. 3B is an illustrative block diagram of a controller circuit board as an exemplary implementation of one of the multiple controllers as shown in FIG. 3A, according to some embodiments;

FIG. 3C is an illustrative block diagram of pin arrangement in an exemplary implementation of pin connector on the controller circuit board as shown in FIG. 3B, according to some embodiments;

FIG. 4A is an illustrative circuit diagram of an exemplary implementation of the controller circuit board as shown in FIG. 3B with a processor, according to some embodiments;

FIGS. 4B-4C illustrate exemplary configurations of the controller circuit board as shown in FIG. 4A for configuring respective battery systems having different voltage ratings, according to some embodiments;

FIG. 5A is an illustrative circuit diagram of an exemplary implementation of the controller circuit board which is similar to the embodiment shown in FIG. 4A, according to some embodiments;

FIGS. 5B-5D illustrate exemplary configurations of the controller circuit board as shown in FIG. 5A for configuring respective battery systems having different voltage ratings, according to some embodiments;

FIG. 5E illustrates an exemplary configuration of the controller circuit board as shown in FIG. 5A that can be used for identification of a subset of plurality of sets of electrochemical cells, according to some embodiments;

FIG. 5F illustrates an exemplary configuration of multiple controller circuit boards as shown in FIG. 5E that can be used for identifying multiple battery systems connected with common bus bars, according to some embodiments;

FIG. 6A illustrates a block diagram of a detection circuitry of an exemplary implementation of the controller circuit board as shown in FIG. 3B that may be configured to detect one or more faulty switches on the controller circuit board, with example logical states of the detection circuitry when there are no faulty switches, according to some embodiments;

FIG. 6B illustrates a block diagram of the detection circuitry as shown in FIG. 6A, with example logical states of the detection circuitry when there is at least one faulty switch, according to some embodiments;

FIG. 7 is a flow diagram of an exemplary method for changing an electrical configuration of sets of one or more electrochemical cells relative to one another according to a commanded configuration of battery systems, according to some embodiments;

FIG. 8 is a flow diagram of an exemplary method for identifying sets of electrochemical cells in one or more battery systems, according to some embodiments; and

FIG. 9 is a flow diagram of an exemplary method for a soft-start process that may be implemented in changing the electrical configuration of sets of one or more electrochemical cells relative to one another, according to some embodiments; and

FIG. 10 is a flow diagram of an exemplary method for performing auto-balancing of one or more sets of electrochemical cells in a battery system, according to some embodiments.

### DETAILED DESCRIPTION

Multiple battery packs and systems may be provided to customers as modular components that may be assembled together in any number of different configurations to suit different needs. For example, multiple sets of electrochemical cells may be connected in parallel to provide a higher current, or in series to increase output voltage. However, the inventors have recognized and appreciated that conventional battery systems or modular components thereof cannot be easily configured to meet the user's needs. For example, a larger battery system designed to provide a high current may require a controller with a higher rating. This increases the size requirement for the controller, and thus, the cost of making the controller and components thereof.

The inventors have further recognized and appreciated that conventional battery systems are inflexible. For example, when multiple battery packs are stacked together to provide a higher current, the controllers associated with respective battery packs of the multiple battery packs cannot meet the rating requirement of the stacked multiple battery packs. This leads to not only redesign of the battery layout but also the controller. Furthermore, the inventors have recognized and appreciated that the cell layout in a conventional battery system cannot be easily configured or reconfigured in a flexible manner.

To solve the aforementioned technical problems and/or other technical problems, the inventors have recognized and appreciated that it may be advantageous to provide controllers that can be stacked, or otherwise electrically connected together, to accommodate a higher rating than that of any individual controllers, where any number of controllers can be stacked depending on the current that needs to be drawn to a load. In such configuration, no special or dedicated controllers need to be designed for larger rating battery systems. Furthermore, the inventors have recognized and appreciated that it may be advantageous to provide a controller that uses switches to control the configuration of electrical connections of multiple electrical energy storage devices (e.g., sets of electrochemical cells) in a battery system according to various commanded configurations, without requiring manual connection of the cells. These concepts may either be used individually and/or in combination with one another as detailed further below.

In view of the foregoing, the inventors have developed new technologies for flexible electrical architectures for battery systems. Described herein are various techniques, including a stack of commonly connected controller circuit boards configured to connect to any battery system, or other appropriate types of electrical storage devices, to provide an expandable current/power capacity to meet flexible battery architectures. In some embodiments, the controller circuit boards in the stack may be connected to each other. For example, multiple controller circuit boards may include identical components which are commonly connected. The common connections among the multiple controller circuit boards enable the various components, e.g., the switches on the multiple controller circuit boards to be controlled together by common control signals from a processor. Thus, the currents may be split between the common controlled components of the connected multiple controller circuit boards when they are controlled to be in the same state in some embodiments. In some embodiments, one of the controller circuit boards in the stack may be a base controller circuit board having a processor configured to provide the common control signals to the multiple controller circuit boards.

In view of the above, in some embodiments as described further herein, an overall current drawn by a load from the battery system, or other type of electrical energy storage devices, may be distributed among the plurality of controller circuit boards. As a result, the current drawn by each controller can be maintained below a current rating of the individual controller. The architecture of using multiple controller circuit boards in a stack enables using multiple lower-rating circuit boards to configure and control a battery system of a larger rating.

Described herein are various techniques, including a controller circuit board to be included in a stack of controller circuit boards. The controller circuit board may be configured to configure layout of multiple electrical energy storage devices (e.g., sets of electrochemical cells) in a system (e.g., a battery system) according to a commanded configuration. Each controller circuit board may include multiple pairs of electrical terminals configured to be electrically connected to multiple electrical energy storage devices (e.g., sets of one or more electrochemical cells) in a system. The controller circuit board may further include one or more power terminals configured to be connected to a load and provide power to the load. The controller circuit board may further include a plurality of switches (e.g., solid-state switches, such as Field Effect Transistor (FET) switches) electrically coupled to the plurality of pairs of electrical terminals. The switches may be configured to operate in an open or closed configuration to control the electrical connection of pairs of electrical terminals, and thus, control the electrical connection of the electrical energy storage devices (e.g., sets of electrochemical cells) connected to the plurality pairs of electrical terminals. The controller circuit board may further include a plurality of pins (e.g., included in a pin connector) coupled to the plurality of switches to provide control signals thereto.

The various components as described above in the plurality of controller circuit boards may be respectively connected such that the plurality of controller circuit boards are commonly connected. For example, the pairs of electrical terminals on the multiple controller circuit boards may be respectively connected. The plurality of switches on the multiple controller circuit boards may be respectively connected in a similar manner. The pin connectors on the multiple controller circuit boards may also be connected.

In some embodiments including flexible configurations of electrical energy storage devices included in a system, (e.g., a battery system or other appropriate type of system capable of storing electrical energy), the plurality of switches on each controller circuit board may be coupled to the pairs of electrical terminals to electrically connect the electrical energy storage devices (e.g., electrochemical cell blocks, battery packs, or other appropriate groupings of one or more electrochemical cells, capacitors, super capacitors, or other appropriate type of electrical energy storage device) coupled thereto in various configurations. In some embodiments, one or more switches may be coupled to a first pair of electrical terminals and a second pair of electrical terminals. For example, at least a first switch may be disposed along a first electrical path extending between a positive terminal of the first pair of electrical terminals and a positive terminal of the second pair of electrical terminals; at least a second switch may be disposed along a second electrical path extending between a negative terminal of the first pair of electrical terminals and a negative terminal of the second pair of electrical terminals; and a third switch may be electrically coupled to the negative terminal of the first pair of electrical terminals and the positive terminal of the second pair of electrical terminals.

In some embodiments, along the first electrical path, a first switch may be coupled to a positive terminal of the pair of electrical terminals and a positive terminal of the second pair of electrical terminals. Along the second electrical path, a second switch may be coupled to a negative terminal of the first pair of electrical terminals and a negative terminal of the second pair of electrical terminals. In some embodiments, the first and second electrical paths may each extend through a respective power bus and include multiple switches. For example, along the first electrical path, a first switch may be electrically coupled to the positive terminal of the first pair of electrical terminals and a first power bus, and a first additional switch may be electrically coupled to the positive terminal of the second pair of electrical terminals and the first power bus. Thus, the first switch and the first additional switch may form the first electrical path through the first power bus. Along the second electrical path, a second switch may be electrically coupled to the negative terminal of the first pair of electrical terminals and a second power bus, and a second additional switch may be electrically coupled to the negative terminal of the second pair of electrical terminals and the second power bus. Thus, the second switch and the second additional switch may form the second electrical path through the second power bus.

Similar to the above, in some embodiments, one or more switches may also be coupled to other pairs of electrical terminals. Specific configurations of these switches and the electrical energy storage devices are detailed further below in regards to the figures.

As used herein, a power bus may refer to any appropriate type of electrical component that is connected to multiple separate components within an electrical system at a common voltage. For example, an electrical node that is at a desired voltage and that is connected to multiple separate components (e.g., electrical energy storage devices, loads, etc.) may be considered one example of an electrical bus.

In some embodiments, each of the plurality of switches may be configured to operate in a closed or open configuration to connect or disconnect an electrical connection between the multiple pairs of electrical terminals. Thus, the electrical connections of multiple electrical energy storage devices (e.g., sets of one or more electrochemical cells) coupled to the plurality of electrical terminals can be configured in a commanded configuration to provide a commanded voltage, current, or other desired electrical operating parameter. The commanded configuration may include at least an isolated connection, a series connection, a parallel connection, and a combination of series connections and parallel connections of the plurality of sets of one or more electrical energy storage devices (e.g., electrochemical cells).

In some embodiments, each controller circuit board may include one or more power terminals each configured to be connected to a respective electrical terminal and provide a respective voltage to a load. In some embodiments, the controller circuit board may also include a respective switch (e.g., a FET switch) coupled to each power terminal and a positive terminal of a corresponding pair of electrical terminal, where the switch is configured to connect/disconnect the power terminal to/from the positive terminal of the corresponding pair of electrical terminal. In some embodiments, the controller circuit board may include a respective switch (e.g., a FET switch) coupled to each power terminal and a corresponding power bus, where the respective switch is configured to connect/disconnect the power terminal to/from a corresponding power bus.

Via controlling the plurality of switches, the power terminal(s) may be configured to be connected to a load and operate at a commanded voltage. Depending on the embodiment, one or more of the electrical energy storage devices (e.g., sets of one or more electrochemical cells) may also be connected to any desired power terminal. This may include, in some embodiments, connecting a first electrical energy storage device (e.g., set of one or more electrochemical cells) to a first power terminal and connecting a second electrical energy storage devices (e.g., set of one or more electrochemical cells) to a second power terminal in at least one operating mode. This may be in addition to controlling the series, parallel, and/or other desired electrical configuration of the plurality of electrical energy storage devices (e.g., sets of one or more electrochemical cells) in one or more other operating modes.

In some embodiments, a base controller circuit board may include at least one processor (e.g., an MCU) for controlling the multiple switches of the base controller circuit board and/or other controller circuit boards in the stack of controller circuit boards. The processor may be configured to send FET control signals to the plurality of switches to independently control the switches to operate at an open or closed configuration such that the multiple electrical energy storage devices (e.g., sets of electrochemical cells, battery packs) may be electrically connected according to a commanded configuration. Additionally, the processor may receive FET status signals from the plurality of switches. The FET control signals and FET status signals may be carried on one or more signal lines on the multiple controller circuit boards through commonly connected pins.

In some embodiments, a controller circuit board may additionally include a measuring circuitry configured to measure the output of a power terminal. For example, the measuring circuitry may include a resistor. The processor may be coupled to the measuring circuitry to receive the measured state of the measuring circuitry. In some embodiments, the measuring circuitry may be coupled to a switch (e.g., a FET switch) that is configured (e.g., controlled by the processor) to active/deactivate the measuring circuitry. For example, the controller circuit board may operate in a measuring mode and an operating mode. In the measuring mode, the processor sends a FET control signal to the switch to connect the measuring circuitry 450 to the power terminal to be measured to activate the measuring circuitry. The reading of the measuring circuitry may be provided to the processor. In the operating model, the processor sends a FET control signal to the switch to disconnect the measuring circuitry from the power terminal to deactivate the measuring circuitry. In such a configuration, the power terminal may provide an output voltage to a load.

In some embodiments, a controller circuit board may include a detection circuitry to detect one or more faulty switches. The detection circuitry may be coupled to the various switches to detect one or more faulty switches. This can be done by the processor sending FET control signals to the plurality of switches and receiving a FET status signal from the detection circuitry. The processor may compare the FET status signal received from the detection circuitry to an expected state. If the FET status signal does not match the expected state, then the processor may determine that at least a switch on the controller circuit board is faulty; otherwise, the processor may determine that there are no faulty switches.

The flexible battery configurations using actively controlled switches may provide several benefits/opportunities to control a battery system. For example, the inventors have recognized and appreciated that conventional battery systems need manual identification/synchronization of sets of electrochemical cells with their corresponding locations in the overall battery configuration. This can be a laborious task for a user to configure a large battery system with several dozens to hundreds of sets of electrochemical cells. Manual identification of sets of electrochemical cells may also introduce human errors, which may cause subsequent incorrect connections of battery packs. Accordingly, the inventors have developed techniques to simplify and automate the identification/synchronization process to determine which electrical energy storage device (e.g., sets of electrochemical cells) is where in the battery system. This is implemented by determining the associations between the electrical energy storage devices (e.g., sets of electrochemical cells) and the pairs of electrical terminals to which the electrical energy storage devices are connected.

In some embodiments, the processor on the controller circuit board may implement an auto-identification process at the start of operation of a battery system. When a battery system is initialized, or otherwise put into an initiation state (e.g., replacement of cells, when first released from the factory, when a user signal is received, etc.), the plurality of switches on the controller circuit board(s) may be set to the open configuration such that all of the battery packs in the battery system are disconnected. To set up the battery system, the auto-identification process may select a pair of electrical terminals for association, and control the plurality of switches to change an operating state of the electrical energy storage devices (e.g., set of electrochemical cells) connected to the selected pair of electrical terminals. For example, the selected pair of electrical terminals may be connected to a desired power terminal, load, or other desired connection that may change the operating state of the electrical energy storage devices associated with the selected pair of power terminals. Changing the operating state of an electrical energy storage device may include changing a load, voltage, and/or otherwise alternating a connection to the electrical energy storage devices. In response to the operating state change, the electrical energy storage device (e.g., a smart battery) may detect the changed operating state and transmit an acknowledgment signal to the processor of the controller circuit board.

The auto-identification process may include receiving an acknowledgment signal from the electrical energy storage device (e.g., set of electrochemical cells) connected to the selected pair of electrical terminals, and consequently, associating the electrical energy storage device with a location of the selected pair of electrical terminals in the battery system. The associating may include identifying the selected pair of electrical terminals and identifying the electrical energy storage device connected to the selected pair of electrical terminals. The identification information of the electrical energy storage device may be transmitted from the electrical energy storage device, where the identification information may uniquely identify the electrical energy storage device. For example, the identification information may include a device ID, a serial number, a MAC address of the smart battery including the electrical energy storage device (e.g., set of electrochemical cells), and/or other suitable identification information. In some embodiments, the auto-identification process may also receive data containing one or more battery properties. The associations of the electrical energy storage device with the location of the pairs of electrical terminals, and other information containing battery properties as obtained from the auto-identification process may enable subsequent control of the plurality of switches on the controller circuit board(s) to configure the electrical energy storage devices in the battery system.

In some embodiments, the auto-identification process may also be used to identify electrical energy storage device(s) in one or more external battery systems that are connected via one or more common bus bars. Each of these external battery systems may have a respective controller circuit board (or a stack of controller circuit boards) and the controller circuit boards (or stacks thereof) of the external battery systems may be commonly connected (e.g., via common pins) and controlled by common control signals. Thus, the auto-identification process may identify one or more electrical energy storage devices in the external battery systems and associate them with the location of the pairs of electrical terminals, in the same manner as described above and further herein.

The inventors have recognized and appreciated that, when a switch is switched from an open configuration to closed configuration, the electrical connection of electrical terminals caused by the close of the switch may introduce an in-rush current that could trip the battery system into short circuit. This may be of particular relevance at the start of operation of a battery system when multiple switches are switched from an open to closed configuration at the same time. Accordingly, the inventors have developed techniques for a soft start process, which may include alternating the one or more switches between an open configuration and closed configuration during transition of states for the switches at a desired rate to reduce the current during startup. For example, appropriate rates for cycling the one or more switches between an open and closed state in a desired configuration may be in any suitable range. When a switch is switched from an open configuration to a closed configuration, or from a closed configuration to an open configuration, the switch is turned on and off alternatively to reduce the inrush or outrush current spikes associated with switching. As a result, average power delivered to the load can be reduced and an excessively high current during startup of the battery system can be avoided. In some embodiments, the alternation of open/closed configuration for a switch may be performed for a short time period (e.g., milliseconds) before the switch is switched to full open or closed configuration. In some embodiments, the on/off cycling of switches may be implemented by using a pulse width modulation (PWM) circuitry to modulate FET control signals to the switches.

The inventors have appreciated and acknowledged that battery balancing of an electrical energy storage device (e.g., a set of one or more electrochemical cells) while still operating the battery system may be desired. For example, upon detecting an electrical energy storage device, in which a set of one or more electrochemical cells are out of balance (i.e., a different state of charge) than the other sets of one or more electrochemical cells, the identified set of one or more electrochemical cells may be taken out of electrical connection with the other sets of one or more electrochemical cells of the battery system and connected to a battery balancer, charging circuit, or other appropriate circuitry to charge the cell to a desired state of charge to balance it with the other sets of one or more electrochemical cells in the battery system. This may be accomplished using the flexible battery connection architectures disclosed herein. Accordingly, other benefits from the flexible battery configurations as describe above and further herein in detail may include flexible architectures and processes for performing auto-balancing of one or more sets of electrochemical cells, without requiring to physically take any cells out of the battery system.

In some embodiments, an auto-balancing process starts with determining that the plurality of electrical energy storage devices (e.g., sets of one or more electrochemical cells) include one or more imbalanced electrical energy storage devices. Various techniques may be used to detect the imbalanced battery cells. For example, a smart battery containing a set of one or more electrochemical cells may determine that the electrochemical cell(s) need to be balanced, and subsequently communicate a signal to the controller circuit board indicating that the battery is in need of balancing using coulomb counting, state of charge determinations using individual voltages for the different sets of electrochemical cells, and/or using any other appropriate technique for determining imbalanced sets of one or more electrochemical cells. For example, in some embodiments, the controller circuit board may be configured to control the switches to isolate the imbalanced electrical energy storage devices (e.g., set of one or more electrochemical cells) and measure the output of the electrical energy storage devices, such as voltage or current, to determine if the electrochemical cell(s) are imbalanced.

The auto-balancing process may further include changing a connection of the one or more imbalanced sets of one or more electrochemical cells, including, for example, controlling one or more of the plurality of switches to disconnect the imbalanced cells from the remaining sets of one or more electrochemical cells in the battery system. The process may further include connecting the imbalanced cells to a charging circuit to perform a balancing charge to a desired state of charge (e.g., a desired voltage, stored coulomb count, etc.). The auto-balancing techniques may be applied to one or more sets of one or more electrochemical cells arranged in any suitable configuration. The techniques may also be applied to auto-balancing one or more groups of electrochemical cells, each group having multiple sets of one of more electrochemical cells. In some embodiments, the techniques may also be applied to auto-balancing any electrochemical cell or groups of electrochemical cells in a configuration including multiple battery systems. For example, two battery systems may be connected by bus bars. Any electrical energy storage device(s) in one system may be taken out for balancing while electrical energy storage device(s) in another system on a different wing of the bus bars may be connected to a load and provide power to the load.

Various embodiments described above and further herein include the use of switches that can be independently controlled and capable of moving between open/closed states to disconnect/connect various electrical connections of multiple electrical energy storage devices. In some embodiments, solid-state switches, such as FET switches, may be used in any of the embodiments.

The sets of one or more electrochemical cells as used in various embodiments described above and further herein may refer to any configuration of associating cells with one another within a battery system, where a battery system may include separate housings and/or separate battery packs, separate cell blocks with one or more electrochemical cells in a single integral housing, etc. For example, a battery pack may include a single electrochemical cell, or a set of multiple electrochemical cells, and a battery system may include one or more battery packs.

Various embodiments described above and further herein provide advantages over conventional systems. For example, controlling of larger battery systems may be possible using modular lower power rating components. The flexible architecture enables a large battery system to be built with the stack of multiple battery packs without requiring a dedicated controller of large power rating. Furthermore, the flexible architecture of controller circuit board(s) enables flexible battery architecture/layout to suit various power commands. Other benefits as described above and further herein include auto-identification/synchronization of sets of electrochemical cells, soft start of the battery system and auto-balancing, all without requiring to manually connect the cells or take any cells out of the battery system.

It should be understood that for the purposes of clarity the embodiments described above and further herein are primarily directed to describing systems including sets of one or more electrochemical cells. However, the current disclosure is not limited in this fashion. Specifically, it should be understood that any of the embodiments described herein that make reference to electrochemical cells, electrochemical devices, sets of electrochemical cells, and/or any other similar term are also intended to include the usage of any appropriate type of electrical energy storage device. For example, appropriate types of electrical energy storage devices may include but are not limited to capacitors, electrochemical cells (e.g., batteries, super capacitors, etc.), and/or any other appropriate type of electrical energy storage device capable of being used with the methods and systems disclosed herein as the disclosure is not limited in this fashion.

Turning to the figures, specific non-limiting embodiments are described in further detail. It should be understood that the various systems, components, features, and methods described relative to these embodiments may be used either individually and/or in any desired combination as the disclosure is not limited to only the specific embodiments described herein.

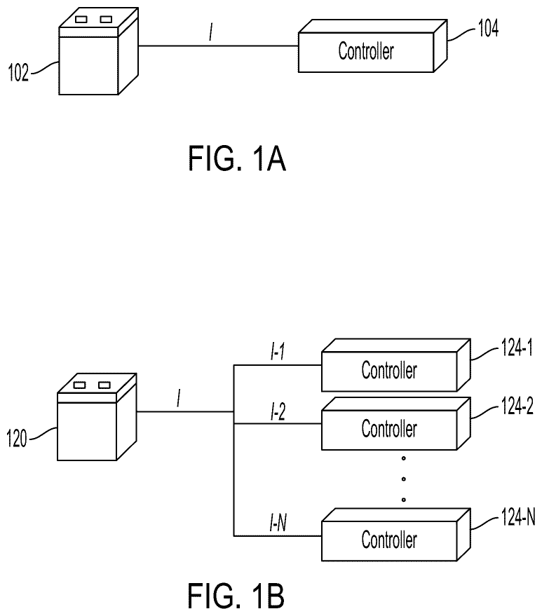

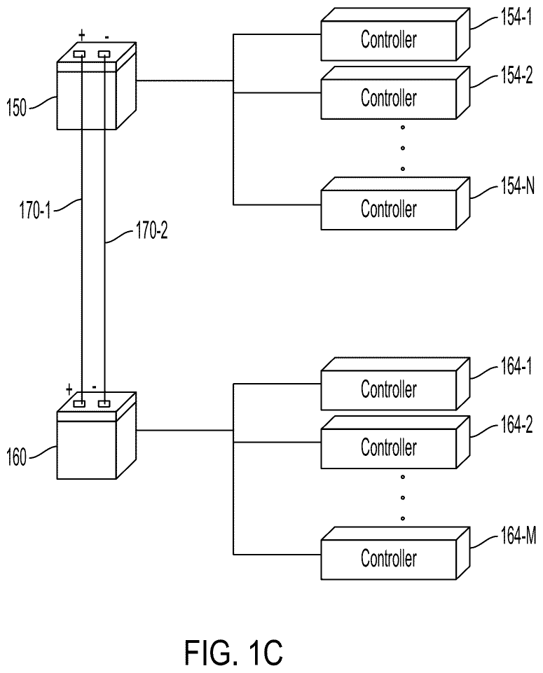

FIG. 1A is an illustrative diagram of a battery system 102 in connection with a controller 104 according to some embodiments. Battery system 102 may include multiple sets of electrochemical cells arranged in a configuration. Each set of electrochemical cells may include one or more electrochemical cells. The configuration of the multiple sets of one or more electrochemical cells may be electrically controlled by the controller 104 to suit the power command of the user. For example, battery system 102 may include multiple battery packs, cell modules, or other grouping of electrochemical cells, each comprising one or more electrochemical cells. In a non-limiting example, a battery pack may include an appropriate number and type of sets of electrochemical cells to provide a voltage of 12 V, 24 V, 48 V, and/or any other desired voltage depending on the number of sets of one or more electrochemical cells and the potential configurations of the sets of one or more electrochemical cells. For example, a controller 104 may electrically configure four sets of electrochemical cells to be connected in series where each set of electrochemical cells may provide a voltage of 12, V and thus when connected in series, may provide a voltage of 48 V. In another configuration, controller 104 may electrically configure four battery packs to be connected in parallel to provide a voltage of 12 V with a higher current rating. It is appreciated that controller 104 may electrically configure the battery packs in the battery system to be connected in any suitable combination of parallel and series connections to achieve a commanded voltage, current, and/or power rating. As such, a flexible battery architecture may be enabled to suit various power, voltage, and/or current commands.

Additionally, and/or alternatively, a controller may include a communication interface configured to communicate with a battery system or another controller. For example, the controller may also receive battery status signals from the battery system associated with the controller and monitor the status of the battery system. Additionally, and/or alternatively, the controller associated with a smart battery system may be configured to communicate with controllers associated with other smart battery systems via a communication network, wired or wirelessly (e.g., a mesh wireless network). Details of the battery system, the controller, and the operation of the controller will be further described.

FIG. 1B is an illustrative diagram a battery system 120 in connection with multiple controllers 124s according to some embodiments. FIG. 1B shows a variation of the configuration in FIG. 1A, with the difference being that battery system 120 may be connected to multiple controllers, e.g., 124-1, 124-2, . . . 124-N, instead of a single controller. In some embodiments, the multiple controllers 124s are commonly connected to the battery system 120. Each of the controllers 124s may have a similar configuration as controller 104 as described herein (FIG. 1A). In such a configuration, an overall current drawn by a load from the battery system 120, e.g., I, may be distributed among the plurality of controllers 124-1, 124-2, . . . , 124-N, where the current drawn in each controller is I-1, I-2, . . . , I-N. As a result, the current drawn through each controller may be less than the total current draw, and thus, may be maintained below a current rating of the individual controller.

In some embodiments, a current rating of a controller may indicate a safe condition for the controller such that, when the controller is operating under such rating, the ratings of all of the components on the controller are also not exceeded and the components on the controller can safely operate. For example, a controller may include a circuit board having a plurality of electronic components, such as switches (mechanical or solid-state switches, such as FET switches) and/or other electronic components. Each of these components may have a respective current rating. When the current rating of the controller is not exceeded, the current ratings of the components on the controller are also not exceeded.

With reference to FIG. 1B, when multiple controllers are used with a battery system, the current rating requirement for each controller may be lower than what would be required when a single controller is connected to the battery system because the overall current drawn to the battery system is distributed among the multiple controllers (e.g., I=I-1, I-2, . . . , I-N). As a result, the current drawn to each individual controller is lower than the overall current drawn to the battery system. This configuration enables smaller components to be used for a controller (because of lower rating requirement), which may result in reduced complexity of circuit board design and cost of manufacturing a controller. This also may eliminate the need to design and manufacture a high rating controller dedicated to battery systems of a high power rating, though the disclosed controllers may have any appropriate voltage, current, and/or power rating as the disclosure is not so limited. Additionally, using multiple controllers may provide advantages and flexibility in combining any suitable number of controllers of a lower rating to control a large battery system with a higher power rating. Depending on the power rating of the battery system, more controllers or fewer controllers may be used.

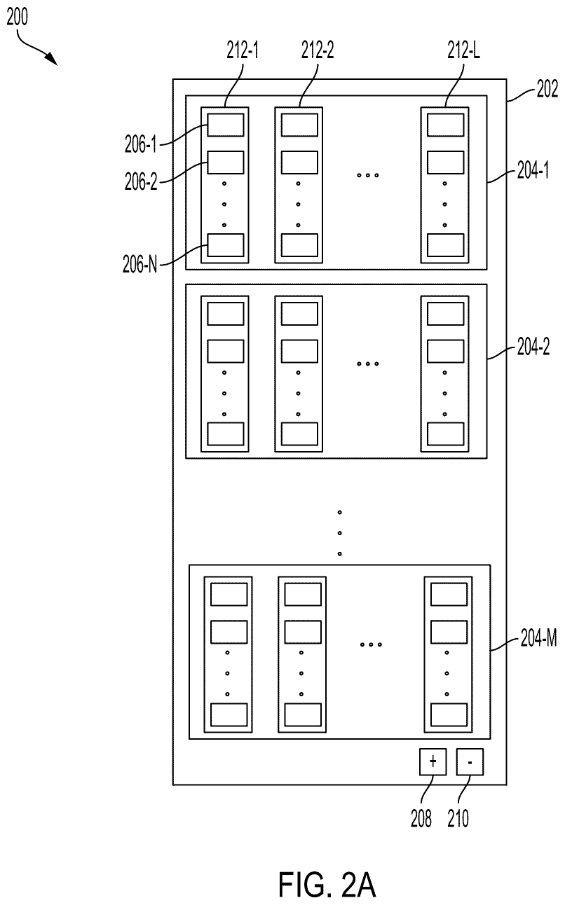

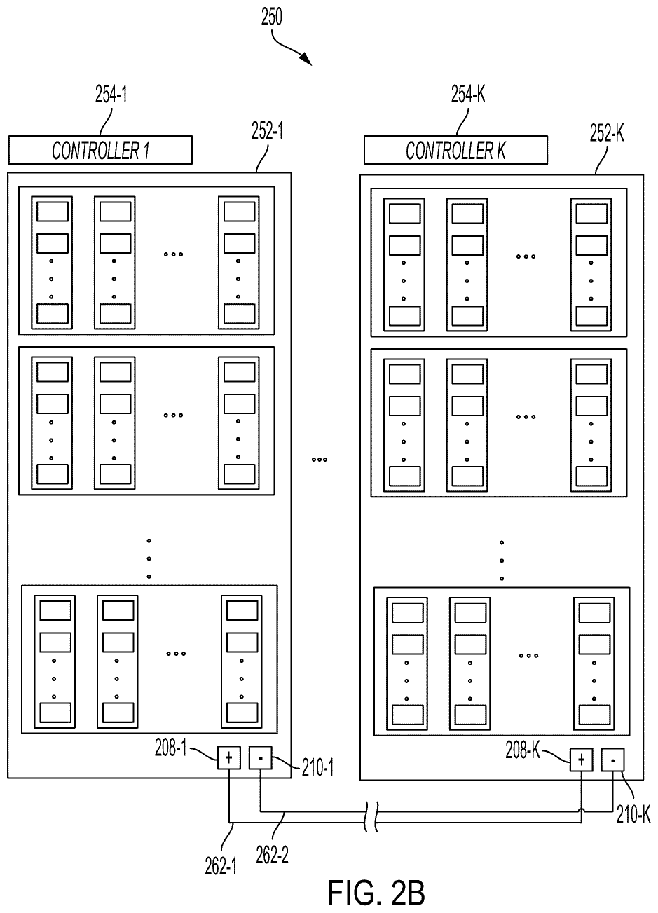

FIG. 1C is an illustrative diagram of multiple battery systems each connected with respective sets of controllers according to some embodiments. As shown, multiple battery systems 150, 160 may be connected, e.g., by bus bars 170-1/2, which respectively connect positive terminals and negative terminals of the battery systems. Each of the battery systems 150, 160 may be configured in a similar manner as battery systems 102 (FIG. 1A), 120 (FIG. 1B). Further, each battery system may be controlled by one or more controllers as shown in FIGS. 1A-1B. Accordingly, the current that is drawn collectively from battery systems 150, 160 is distributed among the multiple controllers (e.g., 154s, 164s), where the power rating of each individual controller may be lower than that for battery systems 150, 160. The configurations of FIGS. 1A-1C enable the flexibility in configuring and monitoring battery systems in various arrangements, which are further described with reference to FIGS. 2A-2B. Further, although it is shown in FIG. 1C that two battery systems are connected by bus bars, it is appreciated that any suitable number of battery systems may be connected in a similar manner.

FIG. 2A is an illustrative diagram of multiple sets of electrochemical cells which may be arranged in multiple groups in a battery system, according to some embodiments. Battery system 200 may implement any battery system described in FIGS. 1A-1C, such as battery system 102, 120, 150, 160. Accordingly, battery system 200 may be configured via one (e.g., FIG. 1A) or multiple controllers (e.g., FIGS. 1B-1C). In some embodiments, battery system 200 may include a single battery system 202. Battery system 202 may include a plurality of electrochemical cells and power terminals (208, 210). The plurality of electrochemical cells, e.g., 206-1, 206-2, . . . , 206-N may, or may not, be arranged in multiple parallel groups of one or more electrochemical cells, e.g., 212-1, 212-2, . . . , 212-L. In either case, the electrochemical cells may be separated into different in a plurality of sets of one or more electrochemical cells, e.g., 204-1, 204-2, . . . , 204-M. Thus, each set of electrochemical cells may include one or more electrochemical cells. For example, a set of electrochemical cells 204-1 may include one or more electrochemical cells, e.g., 206-1, 206-2, . . . , 206-N which may be optionally be arranged into a single group or two or more parallel groups. The sets 204-2, . . . , 204-M may each be configured in a similar configuration as the set 204-1.

In some embodiments, the multiple sets of electrochemical cells, e.g., 204-1, 204-2, . . . 204-L may each be a battery pack, cell block, or other desired grouping of electrochemical cells. A desired configuration of the sets of one or more electrochemical cells may be implemented by electrically connecting the multiple battery packs, where the electrical connections can be controlled by the controller connected to the battery system using a combination of parallel and/or series connections to provide a desired voltages, current, and/or power.

It is appreciated that any suitable configuration of the electrochemical cells may be implemented with disclosed systems and methods. It is further appreciated that not all of the electrochemical cells shown in the battery system 202 may be used in all operating modes, depending on the commanded voltage, current, and/or power command. For example, a subset of the sets of one or more electrochemical cells in system 202 may be connected, whereas other sets of one or more electrochemical cells in system 202 may not be used (and thus, are not connected to the power terminals) in some operating modes. In a non-limiting example, one or more sets of one or more electrochemical cells may be connected to a load to provide power, whereas one or more other sets of one or more electrochemical cells may be taken out of the battery system (e.g., not connected to the remaining sets of one or more electrochemical cells in the battery system) and connected to a charging circuit for balancing and/or other purposes. Techniques for auto-balancing one or more electrochemical cells are further described elsewhere herein.

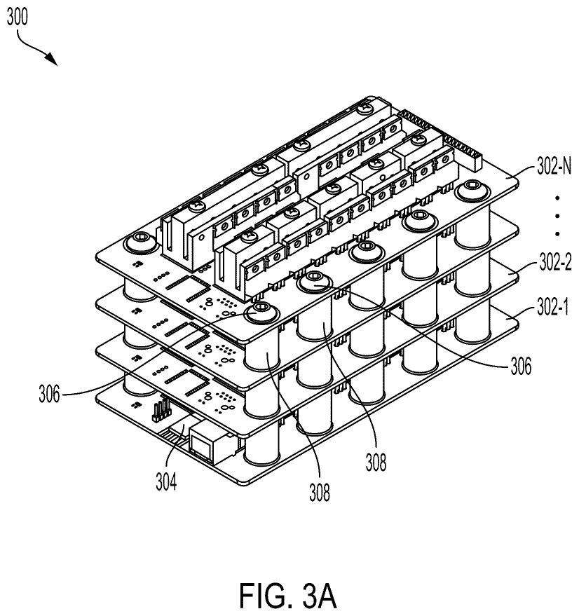

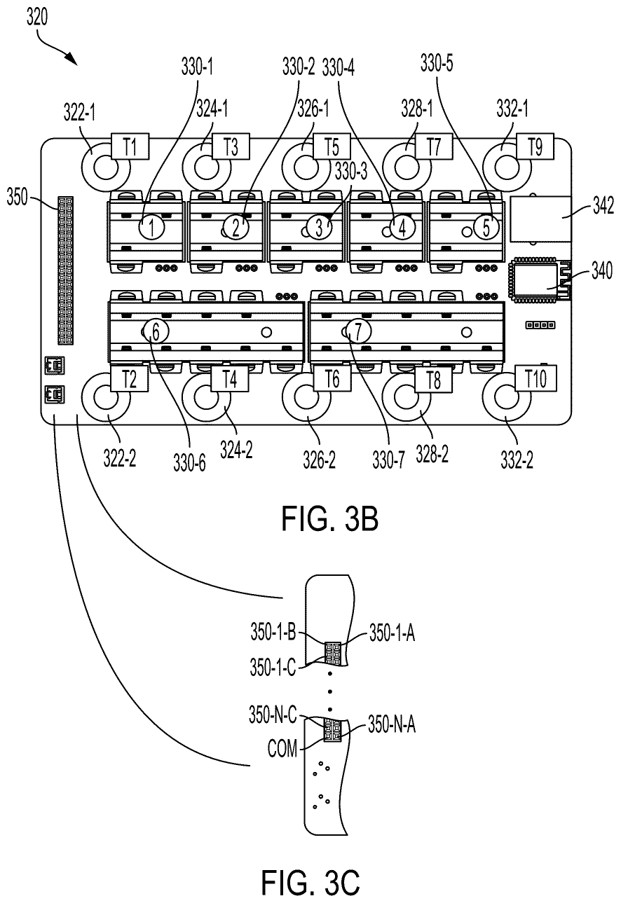

FIG. 2B is an illustrative diagram of multiple battery systems which are connected by bus bars, according to some embodiments. In some embodiments, in configuration 250, multiple battery systems (e.g., 252-1, 252-2, . . . , 252-K) may be connected by bus bars (262s). Each of the battery system 252s may have a similar configuration as battery system 202 (FIG. 2A). In some embodiments, each of battery system 252s may have a respective controller, e.g., 254-1, . . . , 254-K, which may be a single controller (e.g., 104 in FIG. 1A) or stack of controllers (e.g., 124s in FIG. 1B). The bus bars may connect the power terminals (e.g., positive and negative terminals) of each of the battery systems 252s (e.g., 208-1, 210-1, 208-2, 210-2, . . . , 208-K, 210-K). Although it is shown that the bus bars have two bars connecting two power terminals of each battery system, it is appreciated that the bus bars may have one bar or more than two bars, or any suitable number of bars. It is appreciated that the multiple battery systems in configuration 250 may be connected to provide power at a higher rating than that of any individual battery systems. In some embodiments, the various electrical connections for configuring a battery system are realized by switches (e.g., solid-state switches), which are further described with reference to FIGS. 3-10.

FIG. 3A is an illustrative block diagram of multiple controller circuit boards of an exemplary implementation of multiple controllers as shown in FIG. 1B-1C, according to some embodiments. A stack of controller circuit boards 300 may implement the multiple controllers 124s in FIG. 1B, or 154s, 164s in FIG. 1C, for example. As shown in FIG. 3A, the stack of controller circuit boards 300 may include multiple controller circuit boards 302-1, 302-2, . . . , 302-N. These controller circuit boards may be connected to each other. For example, multiple controller circuit boards may include identically components which are commonly connected. Components on a controller circuit board will be further explained with reference to FIG. 3B. In some embodiments, the stack of controller boards may include a base controller circuit board, e.g., 300-1. The base controller circuit board may include a processor 304 (e.g., a micro-controller unit, MCU) configured to control various components of the stack of multiple controller boards (e.g., any components on the controller boards). Additionally, the base controller circuit board (e.g., 302-1) may include communication interface(s) for communicating to other battery systems, and/or other circuitry as will be further described with reference to FIG. 3B.

FIG. 3B is an illustrative block diagram of a controller circuit board as an exemplary implementation of one of the multiple controllers as shown in FIG. 3A, according to some embodiments. Controller circuit board 320 may implement any of the circuit boards in the stack of controller circuit boards 300, controllers 124s in FIG. 1B, or controllers 154s, 164s in FIG. 1C, for example. In some embodiments, controller circuit board 320 may also implement a single controller, e.g., 104 in FIG. 1A. As shown in FIG. 3B, controller circuit board 320 may include multiple pairs of electrical terminals (e.g., 322-1/2, 324-1/2, . . . , 328-1/2) configured to be electrically connected to multiple separate sets of one or more electrochemical cells in a battery system. Controller circuit board 320 may further include one or more power terminals (e.g., 332-1, 332-2) configured to be connected to a load, charging circuit, or other appropriate output and/or input of the battery system. Controller circuit board 320 may further include a plurality of switches 330-1, 330-2, . . . , 330-7 (e.g., solid-state switches, such as FET switches) electrically coupled to the plurality of pairs of electrical terminals. The switches 330s may be configured to operate in an open or closed configuration to control the electrical connection of pairs of electrical terminals (e.g., 322-328 as shown), thus control the electrical connection of sets of electrochemical cells connected to the plurality pairs of electrical terminals. Appropriate electrical connections between the switches and power terminals are elaborated on further below.

With further reference to FIG. 3B, controller circuit board 320 may include a plurality of pins 350 coupled to the plurality of switches to provide control signals thereto. In some embodiments, the plurality of pins 350 may be included in a pin connector. FIG. 3C is an illustrative block diagram of pin arrangement in an exemplary implementation of pin connector 350 on the controller circuit board 320 as shown in FIG. 3B. In a non-limiting example, a number of pins, such as 350-1-A, 350-1-B, 350-1-C are dedicated to a first switch, e.g., switch 330-1. In such case, pins 350-1-A, 350-1-B, 350-1-C are connected to switch 330-1 and configured to send control signals to and/or receive status signals from the switch. A subset of the pins connected to each switch may be used to send control signals to the switch, and a subset of the pins may be used to receive status signals from the switch. For example, pins 350-1-A may carry a control signal for switch 330-1, and pins 350-1-B and 350-1-C may be used to receive status signals from the switch.

Returning to FIGS. 3A and 3B, each of the controller circuit boards 302s in the stack of controller boards 300 may include identical components as shown in FIG. 3B. For example, each controller circuit board (302s in FIG. 3A, or 320 in FIG. 3B) may include respective pairs of electrical terminals (322s), respective plurality of switches (330s), and respective plurality of pins (350). These components in the plurality of controller circuit boards may be respectively connected such that the plurality of controller circuit boards are commonly connected. For example, the pairs of electrical terminals (e.g., 322s) on the multiple controller circuit boards are respectively connected, such that a first pair of electrical terminals (e.g., 322-1/2) on a first controller circuit board (e.g., 302-1) are connected to a first pair of electrical terminals (e.g., 322-1/2) on a second controller circuit board (e.g., 302-2); a second pair of electrical terminals (e.g., 324-1/2) on the first controller circuit board are connected to a second pair of electrical terminals (e.g., 324-1/2) on the second controller circuit board, so on and so forth when the separate controllers are appropriate connected to one another during operation of a battery system.

In some embodiments, the plurality of switches (e.g., 330s) on the multiple controller circuit boards may be respectively connected in a similar manner. The pin connectors (e.g., 350) on the multiple controller circuit boards may also be connected. The common connections among the multiple controller circuit boards enable the various components, e.g., the switches on the multiple controller circuit boards to be controlled together by a common control signal from a single processor. As shown in FIG. 3A, a single processor 302 on the base controller circuit board 302-1 may be configured to control the various components on the multiple controller circuit boards 302-1, . . . , 302-N.

With further reference to FIG. 3B, in case controller circuit board 320 is a base board, controller circuit board 320 may further include at least one processor, e.g., processor 340 (e.g., an MCU). The processor 340 may be coupled to the pins 350 on the base controller circuit board and configured to provide the control signals to the switches (e.g., 330s) on multiple controller circuit boards in a stack, through the commonly connected pins 350. Processor 340 may also be configured to receive status signals of switches (e.g., 330) via the pins 350. Additionally, controller circuit board 320 may include one or more interfaces 342, e.g., a communication interface configured to communicate with other smart battery systems. For example, the communication interface on the controller circuit board 320 may be configured to communicate with any suitable battery system that is coupled to the controller circuit board (e.g., battery system 202 or any set of one or more electrochemical cells, e.g., 212s in FIG. 2A).

In a non-limiting example, each set of one or more electrochemical cells (e.g., 212s in FIG. 2A) may be a smart battery pack that has communication capabilities, and may directly communicate with the processor that is coupled to the smart battery pack. In a non-limiting example, the controller circuit board 320 may be configured to communicate with another battery system not coupled to the controller circuit board. For example, with reference to FIG. 1C, battery systems 150, 160 are connected by bus bars 170-1/2, and each battery system may have a separate associated controller (or stack of controller boards). A controller (e.g., a base controller circuit board of the set of controllers 154s) may communicate with another battery system (e.g., 160) not associated with the controller.

Returning to FIG. 3A, in some embodiments, the plurality of controller board 302s may have similar dimensions and may be aligned and stacked. Components on each controller circuit board may be aligned with corresponding components on other controller circuit boards so that they can be commonly connected. For example, the pairs of electrical terminals (e.g., 306s shown on top board 302-N) on each controller circuit board are aligned and connected to each other. However, embodiments in which the components are not aligned with one another when connected are also contemplated. Additionally, as used herein a stack of controllers may refer to a plurality of controllers that are physically stacked one atop another. However, a stack of controllers may also refer to a group of controllers that are electrically connected with one another as disclosed herein even if they are not physically disposed on and/or against one another as the disclosure is not so limited.

In addition to the above, the stack of controller boards 300 may include a plurality of conductive bushings, e.g., 308s, disposed between adjacent controller circuit boards of the plurality of controller circuit boards and configured to connect corresponding pairs of electrical terminals of the adjacent circuit boards. This may both easily connect and enable the stack of controller circuit boards to handle a larger power rating than any individual controller circuit boards in some embodiments. Thus, control a battery system or a combination of multiple battery systems with a higher power rating may be enabled with such an embodiment.

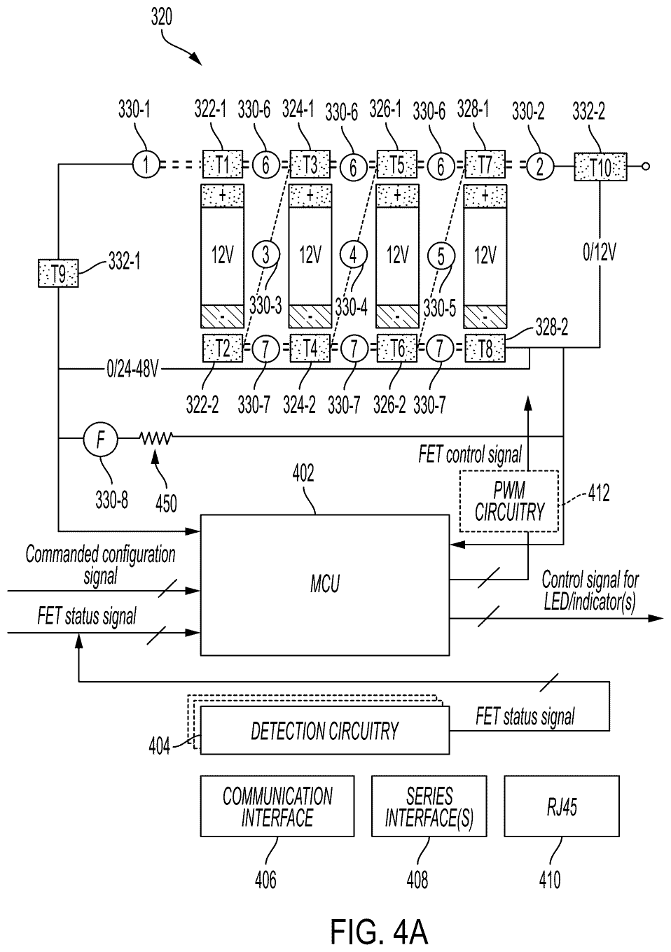

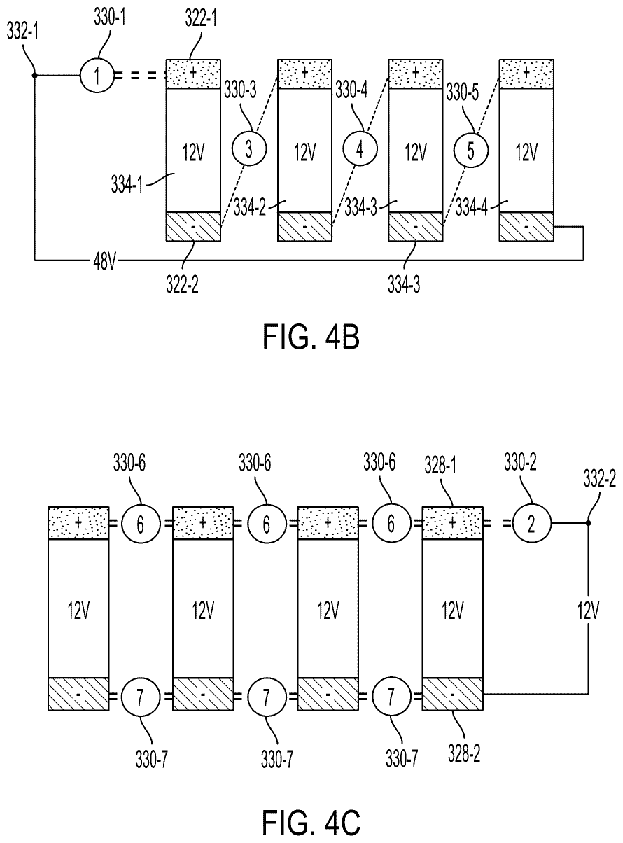

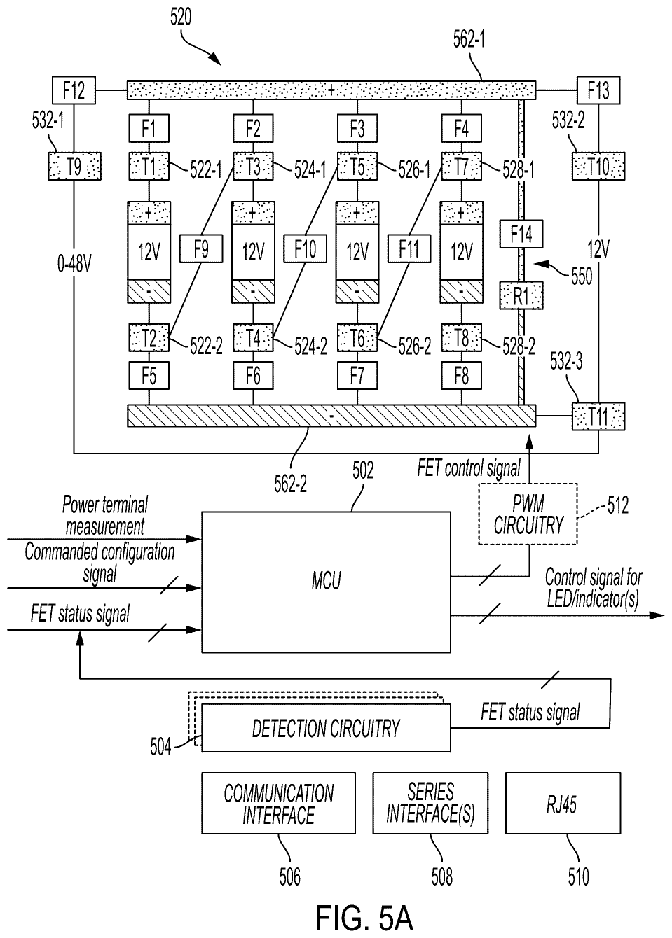

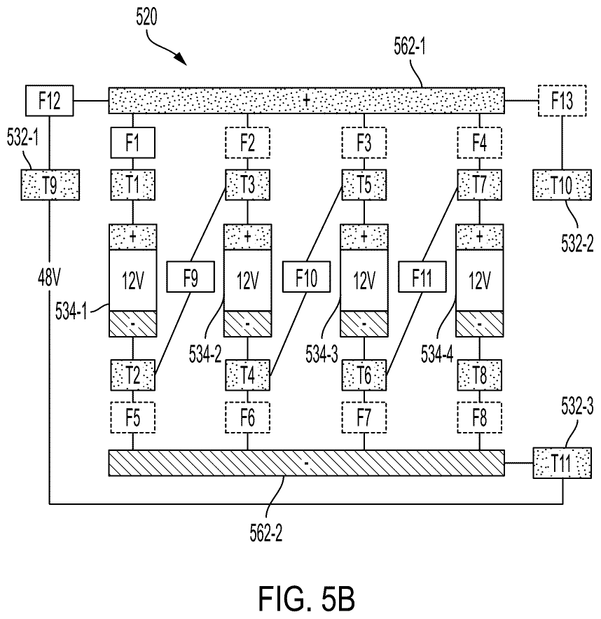

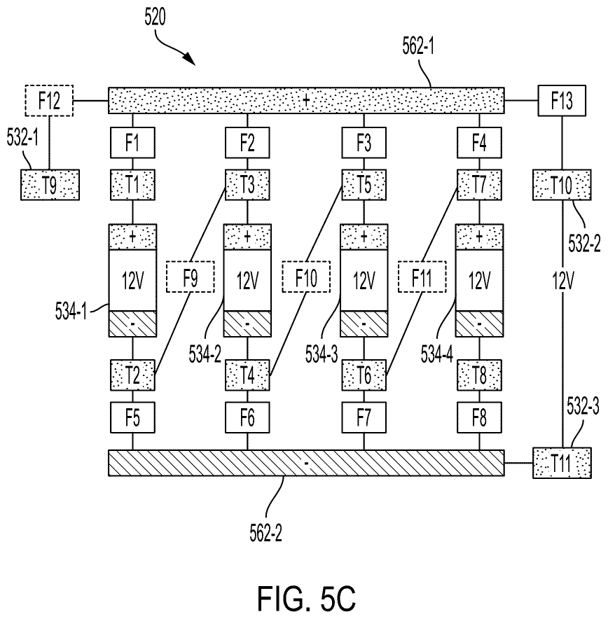

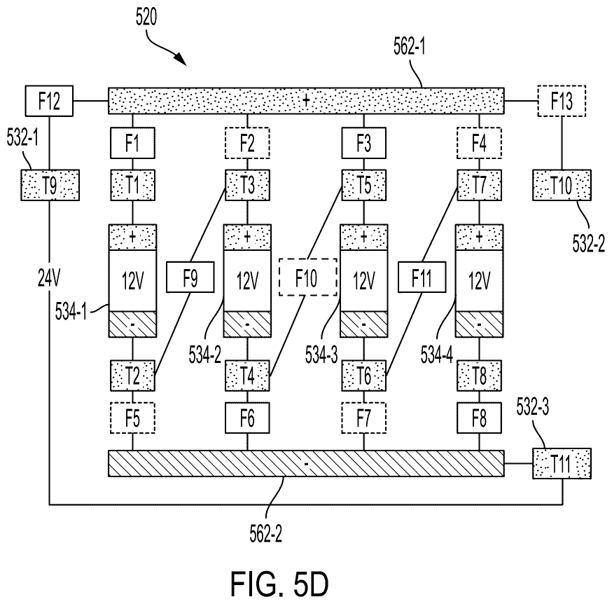

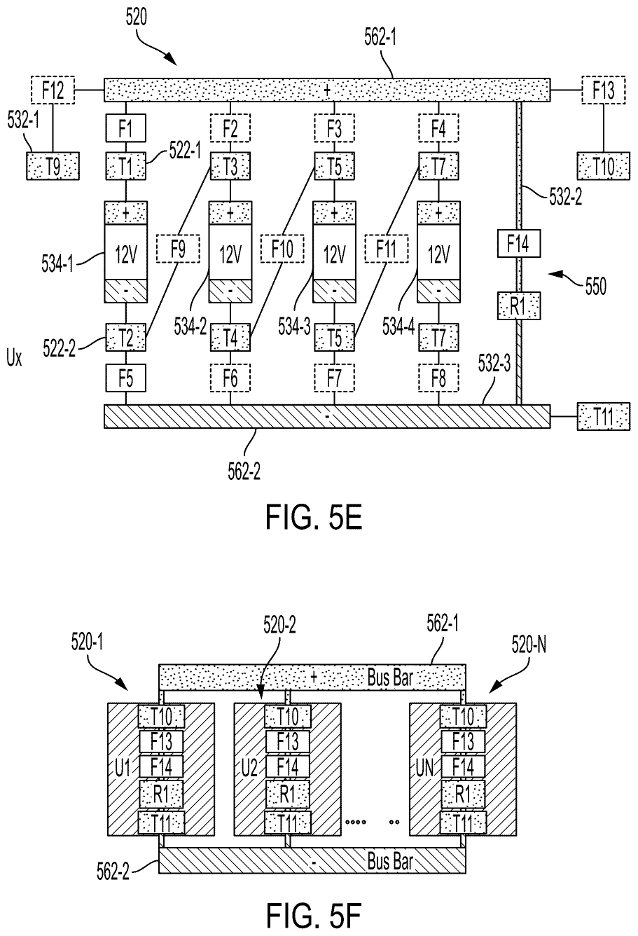

Although four pairs of electrical terminals (e.g., 322s) and seven sets of switches (e.g., 330s) are shown in FIGS. 3A and 3B, it is appreciated that there can be any suitable number of pairs of electrical terminals and any suitable number of switches coupled to the pairs of electrical terminals, depending on the architecture of the battery systems. It is appreciated that the number of pairs of electrical terminals on a controller circuit board and the number of sets of electrochemical cells to be configured may not be a one-to-one correspondence. For example, a controller circuit board having 8 pairs of electrical terminals may have four sets of electrochemical cells coupled thereto, with four pairs of electrical terminals being used and four pairs of electrical terminals being unused. Controller circuit board 320 and variations there of (e.g., controller circuit board 520) are further described in detail with reference to FIGS. 4A-5F.

FIG. 4A is an illustrative circuit diagram of an exemplary implementation of the controller circuit board 320 as shown in FIG. 3B, according to some embodiments. In the circuit diagram shown, each pair of electrical terminals may include a positive terminal and a negative terminal that are configured to respectively connect to the positive and negative terminals of a set of electrochemical cells. For example, four sets of electrochemical cells 334-1, 334-2, 334-3, 334-4 are connected to respective separate pairs of electrical terminals (322-1/2, 324-1/2, 326-1/2, 328-1/2). In this configuration, the positive terminals of the sets of electrochemical cells 334-1, 334-2, 334-3, 334-4 are respectively connected to the positive terminals of the pairs of electrical terminals (e.g., 332-1, 334-1, 336-1, 338-1) and the negative terminals of the sets of electrochemical cells 334-1, 334-2, 334-3, 334-4 are respectively connected to the negative terminals of the pairs of electrical terminals (e.g., 332-2, 334-2, 336-2, 338-2).

With further reference to FIG. 4A, the plurality of switches (e.g., 330s) may be coupled to the pairs of electrical terminals to electrically connect the sets of electrochemical cells coupled thereto in various configurations, the examples of which will be further described in FIGS. 4B-4C. As shown in FIG. 4A, one or more switches may be coupled to a first pair of electrical terminals (e.g., 322-1/2) and a second pair of electrical terminals (e.g., 324-1/2). For example, at least a first switch may be disposed along a first electrical path extending between a positive terminal of the first pair of electrical terminals and a positive terminal of the second pair of electrical terminals; and at least a second switch may be disposed along a second electrical path extending between a negative terminal of the first pair of electrical terminals and a negative terminal of the second pair of electrical terminals. In the example in FIG. 4A, a first switch (e.g., 330-6) may be disposed on a first electrical path (e.g., between electrical terminals 322-1 and 324-1). As shown, switch 330-6 is coupled to a positive terminal of the pair of electrical terminals 322-1 and a positive terminal of the pair of electrical terminals 324-1. A second switch (e.g., 330-7) may be disposed on a second electrical path (e.g., between terminals 322-2 and 324-2). As shown, switch 330-7 is coupled to a negative terminal of the pair of electrical terminals 322-2 and a negative terminal of the pair of electrical terminals 324-2. In addition, a third switch (e.g., 330-3) may be coupled to the negative terminal of the pair of electrical terminals (e.g., 322-2) and the positive terminal of the pair of electrical terminals 324-1. Similarly, one or more switches may also be coupled to other pairs of electrical terminals, such as between pairs of electrical terminals 324-1/2 and 326-1/2, and between pairs of electrical terminals 326-1/2 and 328-1/2.

In some embodiments, each of the plurality of switches (e.g., 330s) may be a solid-state switch, such as a FET switch and may be independently controlled. Each of the plurality of switches may be configured to operate in a closed or open configuration to connect or disconnect an electrical connection between the multiple pairs of electrical terminals. Thus, the electrical connections of multiple sets of electrochemical cells coupled to the plurality of electrical terminals can be configured in a commanded configuration to provide a commanded voltage.

With further reference to FIG. 4A, controller circuit board 320 may include power terminals (e.g., 332-1, 332-2) each configured to be connected to a respective electrical terminal. In some embodiments, controller circuit board 320 may also include a respective switch (e.g., a FET switch similar to other switches 330s) coupled to each power terminal and a positive terminal of a corresponding pair of electrical terminals, where the switch is configured to connect/disconnect the power terminal to/from the positive terminal of the corresponding pair of electrical terminals. For example, a first power terminal 332-1 may be connected to a positive electrical terminal 322-1 of a first set of one or more electrochemical cells via switch 330-1 and a second power terminal 332-2 may be connected to a positive electrical terminal 332-2 of a second set of electrochemical cells via a separate switch 330-2. Via controlling of the plurality of switches, the electrical terminals and power terminal(s) may be appropriate connected to provide power to a desired load and/or connect one or more sets of electrochemical cells to a charging circuit or other appropriate type of circuitry. For example, in FIG. 4A, when switches 330-6 and 330-7 are in closed configuration and switches 330-3, 330-4, 330-5 are in open configuration, the sets of electrochemical cells 334s are connected in parallel. When switch 330-1 is closed and switch 330-2 is open, power terminal 332-1 may provide power at 12 V or other appropriate first voltage. In some examples, the switches may be configured differently such that power terminals operate at different voltages. Examples of output voltages that can be provided at the power terminal(s) as a result of various configurations of the sets of electrochemical cells are further illustrated in FIGS. 4B-4C.

FIGS. 4B-4C illustrate example configurations of the controller circuit board as shown in FIGS. 3B and 4A for configurating respective battery systems having different voltage ratings, according to some embodiments. In FIG. 4B, switches 330-3, 330-4, 330-5 are in a closed configuration to connect the negative terminal and the positive terminal of adjacent pairs of electrical terminals. Switches 330-6 and 330-7 (shown in FIG. 4A) between adjacent electrical terminals of the same polarity are in an open configuration. Thus, sets of electrochemical cells 334-1, 334-2, 334-3, 334-4 are connected in series. Further, switch 330-1 is in a closed configuration to connect the power terminal 332-1 to the positive terminal of the pair of electrical terminals 322-1, thus, power terminal 332-1 may be configured to operate at a first higher voltage (e.g., 48 V) as compared to the other power terminal 332-2 which may be configured to operate at a second lower voltage (e.g., 12 V).

In FIG. 4C, switches 330-3, 330-4, 330-5 (shown in FIG. 4A) are in an open configuration to disconnect the negative terminal and the positive terminal of adjacent pairs of electrical terminals. Switches 330-6 and 330-7 are in a closed configuration to connect the positive terminals of multiple battery sets of electrochemical cells together and connect the negative terminals of multiple sets of electrochemical cells together. Although one reference numeral is used for each of switches 330-6, 330-7, it is shown that multiple switches like 330-6, and 330-7 may be used (see FIG. 4C). Further shown in FIG. 4C, switch 330-2 is in a closed configuration to connect the second power terminal 332-2 to the positive terminal of the pair of electrical terminals 328-1 with the sets of electrochemical cells arranged in a parallel configuration with one another, and thus, providing the second power terminal 332-2 with a second lower operating voltage as compared to the configuration of FIG. 4B.

While specific configurations of the separate sets of electrochemical cells are detailed above, it should be understood that the disclosed methods and systems may be used to provide any desired configuration or set of configurations of any number of sets of electrochemical cells as the disclosure is not so limited. Additionally, as noted previously above, the disclosed flexible control systems may be used to connect different sets of electrochemical cells to different power terminals in some embodiments for balancing and/or any other desired application.

Returning to FIG. 4A, controller circuit board 320 may have at least one processor 402 (e.g., an MCU) for controlling the multiple switches. In some embodiments, the processor 402 may be configured to send FET control signals to the plurality of switches (e.g., 330s) to independently control the switches to operate at an open or closed configuration such that the multiple sets of electrochemical cells (e.g., battery packs) may be electrically connected according to a commanded configuration. Additionally, the processor 402 may receive FET status signals from the plurality of switches. The FET control signals and FET status signals may be carried on one or more signal lines through commonly connected pins (e.g., 350 in FIG. 3B). For example, as shown in FIG. 3C, one signal line (e.g., via pin 350-1-A) is used to carry the FET control signals and two signal lines (e.g., via pins 350-1-B, 350-1-C) are used to carry the FET status signals.

With further reference to FIG. 4A, controller circuit board 320 may additionally include a measuring circuitry 450 configured to measure the output of a power terminal, e.g., 332-1. As shown in FIG. 4A, the measuring circuitry 450 may be coupled to the power terminal (e.g., 332-1) to be measured and ground to measure a state at the power terminal. In some examples, the measuring circuitry 450 may include a resistor. The processor 402 may be coupled to the measuring circuitry 450 to receive the measured state of the measuring circuitry. In some embodiments, measuring circuitry 450 may be coupled to a switch (e.g., a FET switch) that is configured (e.g., controlled by the processor 402) to active/deactivate the measuring circuitry 450. For example, controller circuit board may operate in measuring mode and operating mode. In the measuring mode, the processor 402 sends a FET control signal to switch 332-8 to connect the measuring circuitry 450 to the power terminal 332-1 to activate the measuring circuitry. The reading of the measuring circuitry 450 is provided to the processor 402. In the operating model, the processor 402 sends a FET control signal to switch 332-8 to disconnect the measuring circuitry 450 from the power terminal 332-1 to deactivate the measuring circuitry. In such configuration, the power terminal 332-1 may provide an output voltage to a load.

It is appreciated that a controller circuit board 320 may include a single measuring circuitry configured to measure multiple power terminals. For example, a single measuring circuitry may be selectively connected to one of multiple power terminals (e.g., 332-1, 332-2) to be measured via one or more switches. In some variations, a controller circuit board 320 may include one or more measuring circuitries, each for a respective power terminal. For example, controller circuit board 320 may include an additional measuring circuitry for power terminal 332-2 which is configured in a similar manner as measuring circuitry 450. Thus, the use of any number of measuring circuits may be implemented as the disclosure is not so limited.

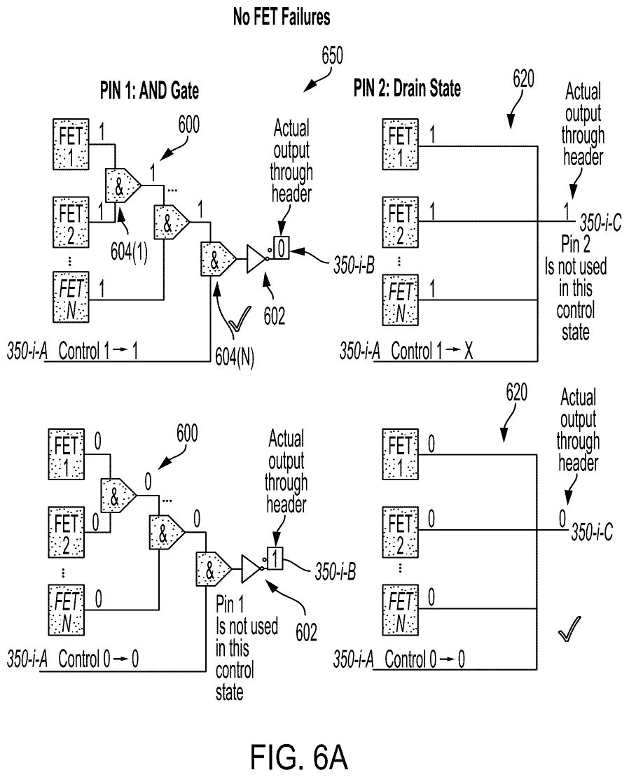

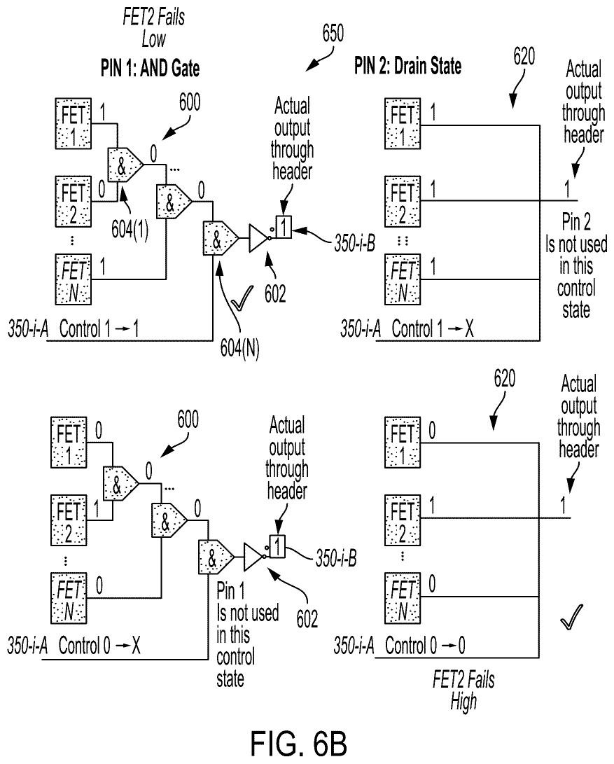

With further reference to FIG. 4A, controller circuit board 320 may include a detection circuitry 404 to detect one or more faulty switches. The detection circuitry 404 may be coupled to the various switches (e.g., 330s) to detect one or more faulty switches. This can be done by the processor 402 sending FET control signals to the plurality of switches (e.g., 330s) and receiving a FET status signal from the detection circuitry 404. In some embodiments, the FET status signal from the detection circuitry 404 may be provided to the processor 402 via the pins (e.g., 350 in FIG. 3B). The processor 402 may compare the FET status signal received from the detection circuitry to an expected state of the detection circuitry. The expected state of the detection circuitry may be based on the FET control signals. For example, the expected state for a detection circuitry may be the state of the FET control signal (e.g., a high or low logical state). In such case, if the FET status signal from the detection circuitry does not match the expected state, then the processor 402 may determine that at least a switch on the controller circuit board is faulty; otherwise, the processor 402 may determine that there are no faulty switches. The operation of the detection circuitry is further described with reference to FIGS. 6A and 6B.

FIG. 5A is an illustrative circuit diagram of a variation of the exemplary implementation of the controller circuit board as shown in FIG. 4A, according to some embodiments. As shown in FIG. 5A, controller circuit board 520 may have a similar configuration as controller circuit board 320 (FIG. 4A). For example, the controller circuit board 520 may include pairs of electrical terminals (e.g., 522, 524, 526, 528), plurality of switches (F's), and power terminals (e.g., 532s) arranged in a similar manner as in controller circuit board 320. For example, at least a first switch is disposed along a first electrical path extending between a positive terminal of the first pair of electrical terminals and a positive terminal of the second pair of electrical terminals; and at least a second switch is disposed along a second electrical path extending between a negative terminal of the first pair of electrical terminals and a negative terminal of the second pair of electrical terminals.

With further reference to FIG. 5A, a difference in controller circuit board 520 in comparison with controller circuit board 320 (FIG. 4A) is that the plurality of switches in controller circuit board 520 may be coupled to the pairs of electrical terminals via a corresponding power bus (e.g., 562-1, 562-2). In the example in FIG. 5A, at least a first switch (e.g., F1, F2) may be disposed along a first electrical path (e.g., between electrical terminals 522-1 and 524-1) through power bus 562-1. For example, switch F1 may be electrically coupled to the positive terminal of the first pair of electrical terminals (e.g., 522-1) and a first power bus (e.g., 562-1). An additional switch (e.g., F2) may be disposed along the first electrical path. For example, switch F2 may be electrically coupled to the positive terminal of the second pair of electrical terminals (e.g., 524-1) and the power bus (e.g., 562-1). Similarly, at least a second switch (e.g., F5, F6) may be disposed along a second electrical path (e.g., between electrical terminals 522-2 and 524-2) through power bus 562-2. As shown, switch F5 may be electrically coupled to the negative terminal of the first pair of electrical terminals (e.g., 522-2) and a second power bus (e.g., 562-2). An additional switch (e.g., F6) may be disposed along the second electrical path. As shown, switch F6 may be electrically coupled to the negative terminal of the second pair of electrical terminals (e.g., 524-2) and the second power bus (e.g., 562-2).

Similar to the configuration of controller circuit board 320 (FIG. 4A), controller circuit board 520 may also include a third switch (e.g., F9) coupled to the negative terminal of the first pair of electrical terminals (e.g., 522-2) and the positive terminal of the second pair of electrical terminals (e.g., 524-1). Similarly, one or more switches may also be coupled to other pairs of electrical terminals, such as between pairs of electrical terminals 524-1/2 and 526-1/2, and between pairs of electrical terminals 526-1/2 and 528-1/2.

In view of the depicted embodiment, in some embodiments, the electrical terminals associated with the positive and negative electrical terminal of each electrical energy storage device (e.g., the sets of one or more electrochemical cells), may be connected to a corresponding positive or negative electrical bus respectively via corresponding switches disposed between the electrical bus and the corresponding electrical terminal. This may be in addition to each of the electrical energy storage devices including a negative electrical terminal that is selectively connectable to a positive electrical terminal of at least one other electrical energy storage device via other corresponding one or more switches.

FIGS. 5B-5D illustrate exemplary configurations of the controller circuit board 520 as shown in FIG. 5A for configuring respective battery systems having different voltage ratings, according to some embodiments. As shown in FIG. 5B, the four sets of electrochemical cells 534-1, 534-2, 534-3, 534-4 are connected to respective pairs of electrical terminals. The plurality of switches F's may be individual controlled such that the four sets of electrochemical cells are connected in series to provide a power of 48 V between power terminals 532-1 and 532-3. As shown in FIG. 5B, switches F1, F9, F10, F11, F8, and F12 are configured to be at the closed configuration (shown in solid boxes) where other switches are configured to be at the open configuration (shown in dashed boxes).

FIG. 5C shows a variation of configuration shown in FIG. 5B, where the plurality of switches F's may be individual controlled such that the four sets of electrochemical cells (e.g., 534-1, 534-2, 534-3, 534-4) are electrically connected in parallel to provide a power of 12 V between power terminals 532-2 and 532-3. As shown in FIG. 5C, switches F1-F8 and F13 are configured to be at the closed configuration (shown in solid boxes) where other switches are configured to be at the open configuration (shown in dashed boxes). FIG. 5D shows a variation of configuration shown in FIGS. 5B and 5C, where the plurality of switches F's may be individual controlled such that the four sets of electrochemical cells (e.g., 534-1, 534-2, 534-3, 534-4) are electrically connected in a combination of series connections and parallel connections to provide a power of 24 V between power terminals 532-1 and 532-3.

As shown in FIG. 5D, switches F1, F9, F6, F3, F11, F8, and F12 are configured to be at the closed configuration (shown in solid boxes) where other switches are configured to be at the open configuration (shown in dashed boxes). As a result, cells 534-1 and 534-2 are connected in series; cells 534-3 and 534-4 are connected in series; and the two groups of series connected cells are connected in parallel between power terminals 532-1 and 532-3. With further reference to FIG. 5A, controller circuit board 520 may include other similar components in controller circuit board 320 (FIG. 4A), e.g., measuring circuitry 550, processor 502, detection circuitry 504, and other interfaces, e.g., communication interface 506, series interface(s) 508, or network interface(s) 510, PWM circuitry 512 etc. Similarly, controller circuit board 520 may also operate in a similar manner as controller circuit board 320 (FIG. 4A).

FIG. 6A illustrates a block diagram of a detection circuitry 650 of an exemplary implementation of the controller circuit board as shown in FIGS. 3B, 4A (e.g., 320), and 5A (e.g., 520) that may be configured to detect one or more faulty switches on the controller circuit board, with example logical states of the detection circuitry when there are no faulty switches, according to some embodiments. FIG. 6B illustrates a block diagram of the detection circuitry as shown in FIG. 6A, with example logical states of the detection circuitry when there is at least one faulty switch, according to some embodiments. In some embodiments, detection circuitry may be coupled to one or more switches for which fault needs to be. As shown in FIGS. 6A and 6B, detection circuitry 650 may include a first detection circuitry 600 and a second detection circuitry 620, which are configured to respectively detect faulty switch(es) at a first state and a second state, which will be described further in detail.

With further reference to FIGS. 6A and 6B, detection circuitries 600, 620 may each include an input (e.g., pin 350-i-A) to receive a FET control signal and an output (e.g., pin 350-i-B for detection circuitry 600, pin 350-i-C for detection circuitry 620) to provide detection signal to the processor (e.g., 402 in FIG. 4, 502 in FIG. 5A), where “i” indicates one of the plurality of switches (e.g., 330s in FIGS. 3B, 4A, and 5A). For example, detection circuitries 600, 620 each is coupled to a plurality of switches (e.g., FET1, FET2, . . . FETN). In some embodiments, switches FET1, FET2, . . . , FETN may be a group of commonly connected switches across multiple controller circuit boards in a stack (e.g., 300 in FIG. 3A). In some embodiments, the group of commonly connected switches may include switches on the multiple controller circuit boards corresponding to one of the plurality of switches (e.g., 330s in FIGS. 3B and 4A, and F's in FIG. 5A). For example, FET1 may be switch 330-1 on controller circuit board 302-1, FET2 may be a switch on controller circuit board 302-2 corresponding to switch 330-1, . . . and FETN may be a switch on controller circuit board 302-N corresponding to switch 330-1. As previously described, these corresponding switches across the multiple controller circuit boards in the stack may be commonly connected via common pins 350. Each group of commonly connected switches may have one or more dedicated input/output pins, e.g., 350-i-A, 350-i-B, 350-i-C (see FIG. 3C) and a respective detection circuitry. As such, there may be multiple detection circuitries similar to detection circuitry 650, each associated with a respective group of commonly connected switches.

Take detection circuitry 650 as an example, if any of the switches coupled to the detection circuitry is faulty, one of the detection circuitries 600, 620 will provide an output signal that does not match an expected state, and thus, the processor (e.g., 402 in FIG. 4A, 502 in FIG. 5A) may determine that at least one of these switches is faulty. If none of these switches is faulty, then detection circuitries 600 or 620 will provide an output signal that matches the expected state, and thus, the processor (e.g., 402 in FIG. 4A, 502 in FIG. 5A) will determine that none of these switches is faulty.

With further reference to FIGS. 6A-6B, detection circuitry 600 may include a plurality of logic gates 604s (e.g., AND gate) that are connected in series, where a first input of each of the logic gates is connected to an output of a preceding logic gate, and a second input of each of the logic gates is connected to a drain of a respective switch. In some embodiments, pin 350-i-A may be coupled to the input of the last logic gate, e.g., 604(N) to provide control input signal to the detection circuitry. In some embodiments, detection circuitry 600 may include a driver 602 (e.g., an inverse gate) coupled to the output of the last of the logic gates connected in series, e.g., 604(N), where the output of the driver 602 may be connected to pin 350-i-B for output to the processor (e.g., 402 in FIG. 4A, 502 in FIG. 5A). In some embodiments, detection circuitry 620 may include one or more logic gates (e.g., OR gates), wherein the inputs of the logic gate(s) may be coupled to the drain of the switches FET1, FET2, . . . , FETN, and an input signal line (e.g., control signal line via pin 350-i-A). The output of the logic gates may be connected to pin 350-i-C for output to the processor (e.g., 402 in FIG. 4A, 502 in FIG. 5A).

With reference to FIG. 6A, detection circuitry 600 may be configured to operate at a first state. In a non-limiting example, a high state control signal (e.g., FET control signal at a high logic state) may be provided to the detection circuitry 600 (e.g., via pin 350-i-A) in the first state. The expected state of the output of the detection circuitry may be low. When none of the switches FET1, FET2, . . . , FETN are faulty, the drain of each switch is at a high state, and thus, the output of the detection circuitry 600 (e.g., at pin 350-i-B) is at a low state, which matches the expected state of detection circuitry 600. In this first state detection, the output of detection circuitry 620 (e.g., at pin 350-i-C) is ignored. At a second state, low state control signal (e.g., FET control signal at a low logic state) may be provided to the detection circuitry 620 (e.g., via pin 350-i-A). The output of detection circuitry 600 (e.g., at pin 350-i-B) is ignored. The expected state of the output of the detection circuitry 620 may be low. When none of the switches FET1, FET2, . . . , FETN are faulty, the drain of each switch is at a low logic state, and thus, the output of the detection circuitry 620 (e.g., at pin 350-i-C) is at a low state, which agrees with the expected state of detection circuitry 620.

FIG. 6B illustrates a block diagram of the detection circuitry as shown in FIG. 6A, with example logical states of the detection circuitry when there is at least one faulty switch, according to some embodiments. Comparing FIG. 6B with FIG. 6A, at the first state (e.g., high state input control signal is provided, low state output is expected at detection circuitry 600), when at least one of the switches FET1, FET2, . . . , FETN is faulty, the drain of the faulty switch is low. As a result, the output of the detection circuitry 600 (e.g., at pin 350-i-B) becomes high, which does not match the expected state of detection circuitry 600. At the second state (e.g., low state input control signal is provided, low state output is expected at detection circuitry 620), when at least one of the switches FET1, FET2, . . . , FETN is faulty, the drain of the faulty switch is high. As a result, the output of the detection circuitry 620 becomes high, which does not match the expected state of detection circuitry 620.

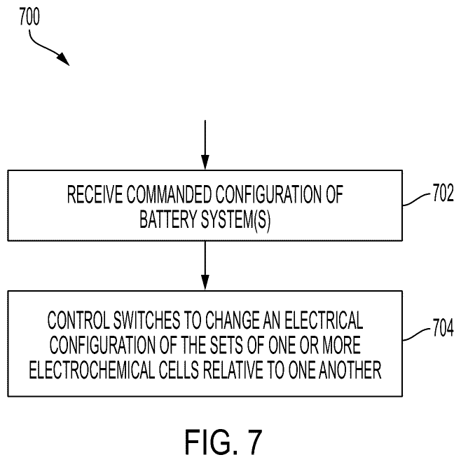

Various embodiments as described above with reference to FIGS. 1A-6B may be implemented to configure and monitor one or more battery systems, as will be described further herein with reference to FIGS. 7-10.

FIG. 7 is a flow diagram of an exemplary method 700 for changing an electrical configuration of sets of one or more electrochemical cells relative to one another according to a commanded configuration of battery systems, according to some embodiments. In some embodiments, method 700 may be implemented in a controller (e.g., 104, any of 124s, 154s, 164s in FIGS. 1A-1C), and/or processor (e.g., 304 in FIG. 3A, 340 in FIG. 3B, 402 in FIG. 4A, 502 in FIG. 5A). The battery system may be any of the set of electrochemical cells described in FIGS. 2A-2B. For example, a battery system may include multiple sets of one or more electrochemical cells (e.g., 212-1, 212-2, . . . ). These sets of electrochemical cells may be respectively connected to multiple pairs of electrical terminals (e.g., 322-1/2, 324-1/2, 326-1/2 . . . ) on a controller circuit board (e.g., 320 in FIGS. 3B and 4A, 520 in FIG. 5A). The multiple pairs of electrical terminals may be connected to a plurality of FET switches (e.g., 330s). Thus, method 700 may be implemented to electrically connect the sets of electrochemical cells in a commanded configuration via the plurality of switches (e.g., 330s) on the controller circuit board.

In some embodiments, method 700 may include receiving a commanded configuration of battery system(s) at act 702 and controlling switches on the controller circuit board to change an electrical configuration of the sets of one or more electrochemical cells relative to one another based on the commanded configuration, at 704. For example, processor 402 (FIG. 4A) or 502 (FIG. 5A) may receive a commanded configuration signal as input, at 702, where the commanded configuration signal indicates a user commanded configuration of a battery system. For example, the commanded configuration may include a series connection, a parallel connection, and/or a combination of series and parallel connections of the sets of electrochemical cells of the battery system. In some embodiments, the commanded configuration signal may be provided by a user device (e.g., via a user device or application communicating with the processor 402 in FIG. 4A, or 502 in FIG. 5A) or by another battery system, a server, or other suitable sources. At act 704, the processor (e.g., 402 in FIG. 4A, 502 in FIG. 5A) may provide FET control signals to the plurality of switches to independently control each switch to operate at an open or closed configuration to disconnect/connect two adjacent pairs of electrical terminals as described in FIGS. 4A and 5A. As a result, as shown in examples in FIGS. 4B-4C and 5B-5D, the various connections of the battery packs (sets of electrochemical cells) can be configured to provide the desired voltage, current, and/or power.

As described above and further herein, a battery system may be controlled by a single controller circuit board (e.g., FIG. 1A) or multiple controller circuit boards (e.g., FIG. 1B). In a single controller circuit board scenario, the plurality of switches and a processor may be disposed on the same board (e.g., FIGS. 4A and 5A), and the method 700 may be implemented in the processor to control the plurality of switches on the same controller circuit board. In a multiple controller circuit boards scenario (e.g., stack 300 in FIG. 3A), the plurality of switches and other components, such as pins and pairs of electrical terminals as described in FIGS. 4A and 5A may be commonly connected among the multiple controller circuit boards. This configuration enables the multiple switches on multiple circuit boards to be controlled by common control signals. Thus, method 700 may be implemented in a base controller circuit board (e.g., 302-1 in FIG. 3A) of a stack of controller circuit boards and provide common control signals to control the plurality of switches in the stack.

In some embodiments, a controller circuit board or a base controller circuit board in a stack of controller circuit boards may be configured to provide common control signals to control the plurality of switches in an external controller. For example, with reference to FIG. 2B, a base controller of a controller (stack) 254-1 may be configured to control the plurality of switches in another controller, e.g., 254-K on a different wing of the bus bars 262s. This example is further illustrated with reference to FIGS. 5E and 5F. FIG. 5E illustrates an exemplary configuration of the controller circuit board as shown in FIG. 5A that can be used for identification of a subset of plurality of sets of electrochemical cells, according to some embodiments. FIG. 5F illustrates exemplary configurations of multiple controller circuit boards as shown in FIG. 5E that can be used for identifying multiple battery systems connected with common bus bars, according to some embodiments.

As shown in FIG. 5E, the controller circuit board 520 may include a measuring circuitry 550, which may be activated/deactivated via the opening/closing of switch F14. Any set of electrochemical cells (e.g., any of sets 534-1, 534-2, 534-3, 534-4) may be isolated from the rest of the sets and the measuring circuitry may be activated to detect the load on the isolated cells. For example, as shown in FIG. 5E, switches F1, F5 may be configured to be at the closed configuration, whereas other switches are configured to be at the open configuration. In addition, switch F14 may be configured to be at the closed configuration to activate the measuring circuitry 550. In such configuration, the set of electrochemical cells 534-1 may be isolated, and the load is measured at circuitry 550.

In the configuration shown in FIG. 5F, each controller circuit board or a controller circuit board in a stack (e.g., 520-1, 520-2, . . . 520-N) may include a controller circuit board 520 (FIG. 5E) and may be associated with a respective battery system of a plurality of battery systems that are connected by bus bars (e.g., 562s). These controller circuit boards may be commonly connected in a similar manner as controller circuit boards in a stack of controller circuit boards are commonly connected (e.g., by common pins, see 350 in FIG. 3B), and thus, may be controlled by common control signals.

It is understood that when each of 520-1, 520-2, . . . 520-N represents a stack of controller circuit boards, each stack may have a respective base controller circuit board (as describe above) which may have a processor configured to send control signals to any other controller circuit boards (or stacks). Any of these base controller circuit boards may be configured to function as a gateway or main controller circuit board and send control signals to any other stacks of controller circuit boards.

The flexible battery configurations using actively controlled switches in a manner as described in method 700 may provide a number of benefits/opportunities to control a battery system. For example, when the battery system is stowed or initially released from the factory, multiple sets of electrochemical cells may be connected to the plurality of pairs of electrical terminals on a controller circuit board or a stack of controller circuit boards, where all of the switches of the controller circuit board(s) (e.g., FET switches, such as, 330s in FIGS. 3B and 4A, and switches F's in FIG. 5A) may be set to be in the open configuration. In this configuration, the battery system is in a power off mode, where all electrical connections of the various sets of electrochemical cells in the battery system are disconnected. Thus, any potential leak or discharges of any of the electrochemical cells can be prevented.

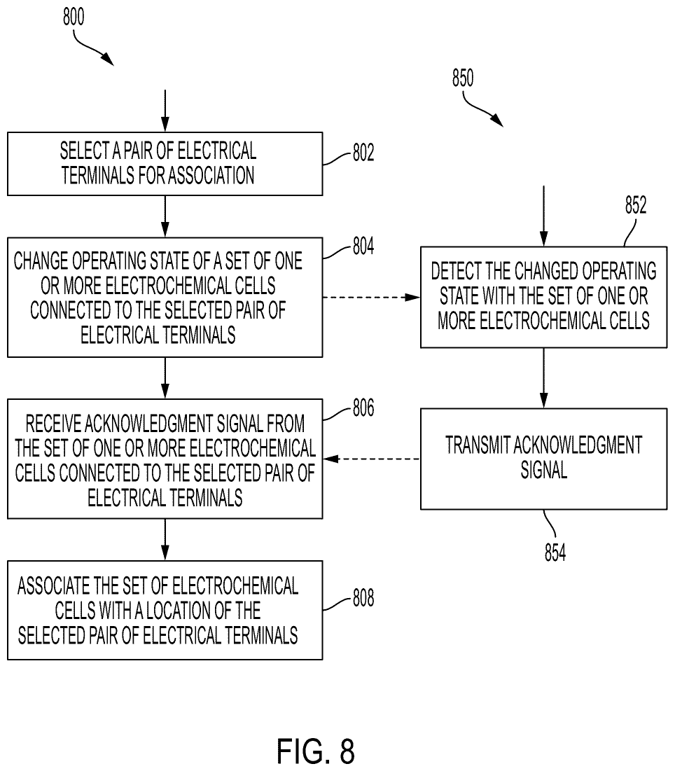

During initial setup of the battery system, the processor (e.g., 402 in FIG. 4A, 502 in FIG. 5A) may be configured to electronically connect or alter connections of the various sets of electrochemical cells in a commanded configuration via the plurality of switches. In doing so, the processor may be configured to automatically identify associations between the sets of electrochemical cells and the pairs of electrical terminals to which the sets of electrochemical cells are connected. Additionally, and/or alternatively, the processor may be configured to automatically identify sets of electrochemical cells in one or more battery systems external to the processor, such as one or more external battery systems connected on one or more bus bars (see FIGS. 2B and 5F). FIG. 8 is a flow diagram of an exemplary method 800 for auto-identification/synchronization of sets of electrochemical cells in one or more battery systems, according to some embodiments.

In some embodiments, method 800 may be implemented in a controller circuit board (e.g., 104 in FIG. 1A, any of 124s in FIG. 1B, 320 in FIGS. 3B and 4A, and 520 in FIG. 5A). A controller circuit board may include a communication interface (e.g., 406 in FIG. 4A, 506 in FIG. 5A) to communicate with any set of electrochemical cells. A set of electrochemical cells may be a smart battery that also includes a communication interface configured to communicate with a controller over a communication network (e.g., wireless mesh network). In some embodiments, the set of electrochemical cells may be part of the smart battery to which the controller circuit board is connected. In some embodiments, the set of electrochemical cells may be part of a battery system external to the controller circuit board. In some embodiments, method 800 may be implemented in a processor such as 304 in FIG. 3A, 340 in FIG. 3B, 402 in FIG. 4A, 502 in FIG. 5A. Method 850 may be implemented in a smart battery connected to the controller circuit board or any battery system external to the battery system to which the controller circuit board is connected. For example, with reference to FIG. 5F, method 850 may be implemented in any of the external battery systems associated with the controller circuit board(s) 520-1, . . . 520-N.

Returning to FIG. 8, in some embodiments, method 800 may start with selecting a pair of electrical terminals for association, at act 802. Method 800 may further control the plurality of switches to change operating state of the set of electrochemical cells connected to the selected pair of electrical terminals, at act 804. In some embodiments, changing the operating state of a set of electrochemical cells may include changing a load, voltage, and/or otherwise altering a connection to the set of electrochemical cells. For example, with reference to FIG. 4A, method 800 may select the pair of electrical terminals 322-1/2 by isolating other pairs of electrical terminals via controlling the other plurality of switches 330 to be in an open state, and changing the operating state of the set of electrochemical cells 334-1 that are connected to the pair of electrical terminals 322-1/2 (e.g., changing the load). In response to the operating state change, the set of electrochemical cells (e.g., a smart battery) may detect the changed operating state, at act 852; and transmit an acknowledgment signal to the processor of the controller circuit board, at act 854.

Method 800 at the processor of the controller circuit board may receive an acknowledgment signal from the set of electrochemical cells connected to the selected pair of electrical terminals, at act 806. For example, changing an operating state of the set of electrochemical cells as described above may include changing the load. In response, the smart battery system including the set of electrochemical cells may experience the load, and subsequently transmit a signal indicating a state of discharge to the controller circuit board. In some embodiments, the communication between the smart battery and the controller circuit board may be wired or wirelessly (e.g., via a wireless mesh network). Consequently, method 800 may receive the signal from the set of electrochemical cells, and associate the set of electrochemical cells with a location of the selected pair of electrical terminals in the battery system, at act 808. In the above example, with reference to FIG. 4A, the set of electrochemical cells 334-1 detects an operating state change, and subsequently sends an acknowledgment signal to the controller. Upon receiving the acknowledgement signal, the controller may associate the physical location of the pair of electrical terminals (e.g., 322-1/2) with the set of electrochemical cells 334-1.

In some embodiments, the association may include identification of the selected pair of electrical terminals and identification of the set of electrochemical cells connected to the selected pair of electrical terminals. Information that identifies the set of electrochemical cells may be transmitted from the set of electrochemical cells to the controller (in addition to the acknowledgment signal). For example, method 800 may receive information that uniquely identifies the set of electrochemical cells, such as a device ID, a serial number, a MAC address of the smart battery including the set of electrochemical cells, and/or other suitable identification information. In some embodiments, method 800 may additionally receive information containing one or more battery properties from the set of electrochemical cells. For example, the one or more battery properties may include a current state of charge, a voltage change upon the change in operating state (e.g., going from 0 to 4.3 v), a voltage across the now connected terminals, and/or any other appropriate battery property.

In some embodiments, the above method may be repeated for each pair of electrical terminals included in a battery system in order to associate each set of one or more electrochemical cells with a corresponding pair of electrical terminals. Thus, a battery system may be both easily and automatically setup in such an embodiment.

In some embodiments, the associations between the sets of electrochemical cells and the pairs of electrical terminals to which the sets of electrochemical cells are connected, as may be determined using method 800, may enable the controller circuit board to automatically identify/synchronize the sets of electrochemical cells with their corresponding locations in the overall battery configuration. In some embodiments, method 800 may be implemented before act 704 (FIG. 7) is executed. Thus, subsequent to identification/synchronization of the sets of electrochemical cells, act 704 may be executed to control the plurality of switches to electrically connect the sets of electrochemical cells, based on identification/synchronization. Additionally, the control of the plurality of switches may also be based on the one or more battery properties of one or more sets of electrochemical cells, e.g., voltage rating as can be obtained in method 800.

Variations of methods 800, 850 for identifying any set of electrochemical cells, including set of electrochemical cells external to the battery system to which the controller circuit board is connected are further described with reference to FIGS. 5E and 5F. In some embodiments, in the configuration as shown in FIG. 5F, act 802 may control the switches to select the pair of electrical terminals 522-1/2, and thus, isolate the set of electrochemical cells 534-1. Act 804 may connect the isolated set of electrochemical cells 534-1 to the load by activating the measuring circuit 550 (e.g., via controlling switch F14 to close). Similarly, all other controller circuit boards (e.g., 520-1, 520-2, 520-3, 520-4 in FIG. 5F) respectively associated with external battery systems may operate in a similar manner. As such, corresponding sets of electrochemical cells (e.g., 534-1) in each of the external battery systems may be isolated and connected to a resistive load. In response to the change of operating state for the isolated sets of electrochemical cells, each of the external battery systems may communicate to the controller (e.g., via a respective communication interface) and transmit a signal indicating a discharge state. The communication between the external battery systems and the controller circuit board may include a wireless communication, e.g., a wireless mesh network, though communication over a wired network is also contemplated. Act 806 may receive the signals from the external battery systems and associate these external battery systems with the pair of electrical terminals (e.g., 522-1/2).

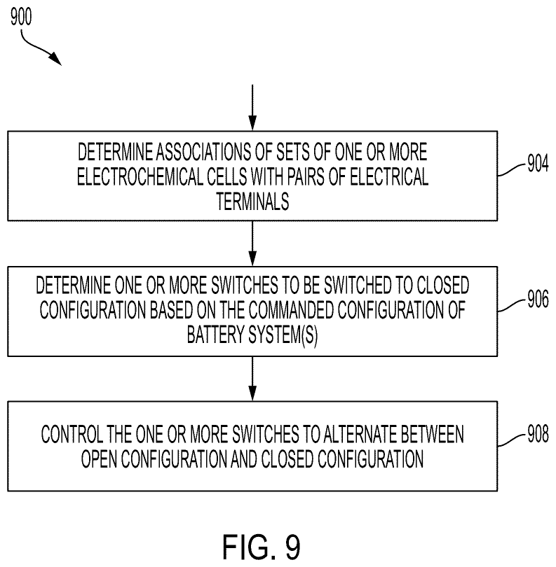

FIG. 9 is a flow diagram of an exemplary method 900 for a soft-start process that may be used in changing the electrical configuration of sets of one or more electrochemical cells relative to one another, according to some embodiments. For example, method 900 may be used to implement act 704 of method 700 (FIG. 7). Thus, similar to method 700, method 900 may be implemented in a controller (e.g., 104, any of 124s, 154s, 164s in FIGS. 1A-1C), and/or processor (e.g., 304 in FIG. 3A, 340 in FIG. 3B, 402 in FIG. 4). In some embodiments, method 900 may start with determining associations of sets of one or more electrochemical cells with pairs of electrical terminals, at act 904. In some examples, act 904 may be performed in method 800 as described in FIG. 8. Alternatively, the sets of one or more electrochemical cells may already be associated with the pairs of electrical terminals. In either case, method 900 may further include determining a subset of the plurality of switches to be switched to the closed configuration based on the commanded configuration of battery system(s), at act 906. For example, as described in examples in FIGS. 5A-5C, some switches may be configured to be switched to the closed configuration to make electrical connections, depending on the commanded configuration.

Returning to FIG. 9, method 900 may further include controlling the subset of the plurality of switches to be switched from open to closed configuration, or from closed to open configuration, to alternate between the open and closed configurations, at act 908. The alternation may be performed during the switching (transition of states) for a short period (e.g., milliseconds) before the switch is switched to full open or closed configuration. The use of alternating open/closed configurations for the subset of the plurality of switches may be performed with a duty cycle with a desired rate of change. Such us of alternating open/closed configurations may decrease any inrush or outrush current that could trip one or more safety systems of the battery system(s) or otherwise result in undesirable operating conditions. Appropriate operating frequencies for alternating the open/closed configurations of the switches may be in any suitable range. The use of the on/off cycling of switches may reduce the average power delivered to the load and avoid short circuit. In some embodiment, a controller circuit board (e.g., 400 in FIG. 4) may optionally include a pulse width modulation (PWM) circuitry 412 configured to modulate the FET control signals with pulse width signals to cause the subset of the switches to alternate between the open and closed configurations. In some embodiments, the pulse width signals can be used for voltage and/or amperage manipulation over the controlled switches.

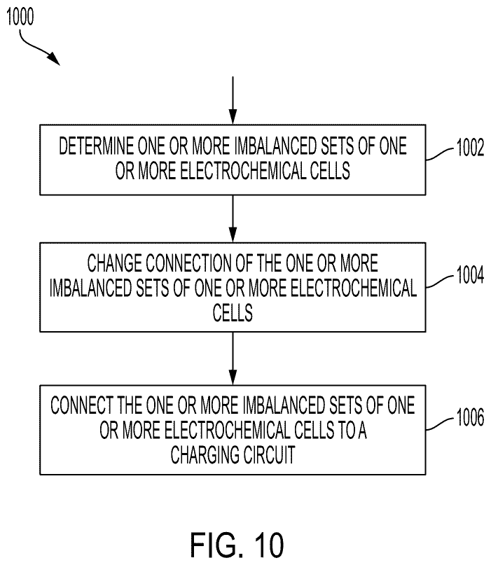

FIG. 10 is a flow diagram of an exemplary method 1000 for performing auto-balancing of one or more sets of electrochemical cells in a battery system, according to some embodiments. In some embodiments, method 1000 may be implemented in a controller (e.g., 104, any of 124s, 154s, 164s in FIGS. 1A-1C), and/or processor (e.g., 304 in FIG. 3A, 340 in FIG. 3B, 402 in FIG. 4). The inventors have appreciated and acknowledged that battery balancing of an electrochemical cell or one or more sets of electrochemical cells may include a set of one or more electrochemical cell(s) being taken out of connection with the other sets of electrochemical cells in the battery system and connected to a battery balancer/regulator to top off the capacity relative to other sets of electrochemical cells in the battery system. Thus, the techniques described herein may enable changing electrical connections of imbalanced battery cells without physically taking the imbalanced battery cells out of the battery system. In some embodiments, method 1000 starts with determining that the plurality of sets of one or more electrochemical cells include one or more imbalanced sets of one or more electrochemical cells, at act 1002.

Various techniques may be used to detect the imbalanced battery cells. In some embodiments, the detection of imbalanced battery cells can be implemented for any set of one or more electrochemical cells upon determining that the set of electrochemical cell(s) need to be balanced based on a determined state of charge, capacity, or other appropriate parameter of the set of electrochemical cells relative to the other sets of electrochemical cells in the battery system. This may include sensors configured to detect these parameters within the overall battery system (e.g., voltage sensors, coulomb counters, etc.), the one or more sets of electrochemical cells corresponding to separate smart batteries configured to determine these parameters and communicate a signal indicating the imbalanced state, OTHERS, and/or any other appropriate method for identifying the presence of one or more imbalanced sets of electrochemical cells. Thus, act 1002 may include obtaining a signal from a set of electrochemical cells or otherwise detecting the presence of a set of electrochemical cells in need of balancing. In some embodiments, the detection of imbalanced battery cells can be implemented in a controller (e.g., 104, any of 124s, 154s, 164s in FIGS. 1A-1C), and/or processor (e.g., 304 in FIG. 3A, 340 in FIG. 3B, 402 in FIG. 4). For example, the controller circuit board may be configured to control the switches to isolate each electrochemical cell or one or more sets of electrochemical cells and operate in the measuring mode as previously described to measure the output of the electrochemical cell(s), such as voltage or current. Upon determining that the output of the set of electrochemical cell(s) is outside a threshold range as compared to the other sets of electrochemical cells, the controller circuit board may determine that the set of electrochemical cell(s) are imbalanced and may need to be balanced.

With further reference to FIG. 10, method 1000 may further include changing a connection of the one or more imbalanced sets of one or more electrochemical cells, at act 1004. For example, changing the connection of the imbalanced cells may include controlling one or more of the plurality of switches to disconnect the set of imbalanced cells from the remaining sets of cells in the battery system. Method 1000 may further include connecting the set of imbalanced cells to a charging circuit, at act 1006. It is appreciated that method 1000 or any act thereof may be performed automatically, at a determined schedule, or manually. For example, the system may perform act 1006 automatically, or at a determine schedule. Alternatively, act 1006 may be performed manually due to a controller of the system receiving a manual command from a user through any appropriate user interface.

It is appreciated that method 1000 may be implemented for auto-balancing one or more sets of one or more electrochemical cells arranged in any suitable configuration, such as what is described above (see FIG. 2). For example, in a battery system including four 12 V sets of electrochemical cells, a set of cells may be taken out of electrical connection with the other sets of cells in the battery system, via change of electrical connections (e.g., act 1004). In some examples, the set of imbalanced electrochemical cells may be connected to a charging circuitry (e.g., via control of switch(es)) for balancing. At the same time, the three remaining sets of electrochemical cells may be electrically connected (e.g., via control of switch(es)) to provide power. For example, the three remaining 12 V sets of electrochemical cells may be connected in parallel to provide power at 12 V. In some examples, two 12 V sets of electrochemical cells may be connected in parallel and to a 12 V charging circuitry, whereas the other two remaining sets of electrochemical cells may be connected in parallel or series and connected to a load to provide power. However, it is appreciated that method 1000 may be applied to balance any number of sets of electrochemical cells for a battery system including any appropriate total number of sets of electrochemical cells.

It is further appreciated that method 1000 may also be applied in auto-balancing any set of electrochemical cells of a battery system in a configuration including multiple battery systems. For example, with reference to FIGS. 2B, any electrochemical cell(s) in one system (e.g., 252-1) may be taken out of use for balancing while electrochemical cell(s) in another system (e.g., 252-K) on a different wing of the bus bars 262s may be connected to a load and provide power to the load.

The above-described embodiments are only exemplary. It is also appreciated that various embodiments described herein may be used for configuring and controlling battery systems for various battery applications, such as various types of vehicles such as a car, a recreational vehicle (RV) or a boat, or other devices, e.g., consumer electronics, industrial machinery, other stationary and/or mobile applications, and/or any other appropriate application for which a battery system may be used as the disclosure is not limited to any particular application.

The above-described embodiments of the present invention can be implemented in any of numerous ways. For example, the embodiments may be implemented in a controller circuit board as described herein using hardware, software or a combination thereof. When implemented in software, the software code can be executed on any suitable processor or collection of processors, whether provided on a single controller circuit board (e.g., 104 in FIG. 1A) or among multiple controller circuit boards (e.g., 124s in FIG. 1B, 154s, 164s in FIG. 1C). Such processor(s) may be implemented as integrated circuits, with one or more processors in an integrated circuit component, including commercially available integrated circuit components known in the art by names such as CPU chips, GPU chips, microprocessor, microcontroller, or co-processor. Alternatively, a processor may be implemented in custom circuitry, such as an ASIC, or semicustom circuitry resulting from configuring a programmable logic device. As yet a further alternative, a processor may be a portion of a larger circuit or semiconductor device, whether commercially available, semi-custom or custom. As a specific example, some commercially available microprocessors have multiple cores such that one or a subset of those cores may constitute a processor. Though, a processor may be implemented using circuitry in any suitable format.

Further, it should be appreciated that the controller circuit board or the stack of controller circuit boards may be embodied in any forms, such as in a single battery enclosure, in separate battery packages, a device external to the battery system associated with the controller, or any suitable forms. In some variations, the one or more controller circuit board may be integrated partially or entirely in a semiconductor chip.

Depending on the nature of the controller circuit board or stacks of controller circuit boards, one or more additional elements may be present. For example, a controller circuit board may include sensors such as a global positioning system (GPS) to sense location and inertial sensors such as a compass, an inclinometer and/o ran accelerometer. The processor may be configured to control these devices to capture data from them and make it available to applications executing on the controller circuit board(s).

As another example, in some embodiments, a controller circuit board may include a network interface to implement a personal area network. Such an interface may operate in accordance with any suitable technology, including a Bluetooth, Zigbee or an 802.11 ad hoc mode, for example.

Such a controller may be interconnected by one or more networks in any suitable form, including as a local area network or a wide area network, such as an enterprise network or the Internet. Such networks may be based on any suitable technology and may operate according to any suitable protocol and may include wireless networks, wired networks or fiber optic networks.

Based on the foregoing disclosure, it should be apparent to one of ordinary skill in the art that the embodiments disclosed herein are not limited to a particular controller circuit board, battery system, set of electrochemical cells, processor, operating system or communication protocol. Also, it should be apparent that the embodiments disclosed herein are not limited to a specific architecture, hardware or software implementation.

Examples of arrangements that may be implemented according to some embodiments include the following:

1. An apparatus for controlling a battery system, the apparatus comprising:
a plurality of pairs of electrical terminals configured to be electrically connected to a plurality of electrical energy storage devices, wherein the plurality of pairs of electrical terminals include at least a first pair of electrical terminals and a second pair of electrical terminals, wherein each pair of electrical terminals include a positive terminal and a negative terminal; and
a plurality of switches configured to be independently controlled between an open configuration and a closed configuration, wherein the plurality of switches include at least:
   at least a first switch disposed along a first electrical path extending between a positive terminal of the first pair of electrical terminals and a positive terminal of the second pair of electrical terminals;
   at least a second switch disposed along a second electrical path extending between a negative terminal of the first pair of electrical terminals and a negative terminal of the second pair of electrical terminals; and
   a third switch electrically coupled to the negative terminal of the first pair of electrical terminals and the positive terminal of the second pair of electrical terminals.

2. The apparatus of example 1, wherein the plurality of electrical energy storage devices comprises a plurality of sets of one or more electrochemical cells.

3. The apparatus of example 2, wherein:
the first switch is electrically coupled to a positive terminal of the first pair of electrical terminals and a positive terminal of the second pair of electrical terminals; and
the second switch electrically coupled to a negative terminal of the first pair of electrical terminals and a negative terminal of the second pair of electrical terminals.

4. The apparatus of example 2, wherein:
the first switch is electrically coupled to the positive terminal of the first pair of electrical terminals and a first power bus; and
the second switch is electrically coupled to the negative terminal of the first pair of electrical terminals and a second power bus.

5. The apparatus of example 4, wherein the plurality of switches further includes:
a fourth switch electrically coupled to the positive terminal of the second pair of electrical terminals and the first power bus; and
a fifth switch electrically coupled to the negative terminal of the second pair of electrical terminals and the second power bus.

6. The apparatus of example 2, further comprising at least one processor configured to control the plurality of switches individually so that the plurality of sets of one or more electrochemical cells are connected in a commanded configuration.

7. The apparatus of example 6, wherein the commanded configuration includes at least an isolated connection, a series connection, a parallel connection, and/or a combination of series connections and parallel connections of one or more of the plurality of sets of one or more electrochemical cells.

8. The apparatus of example 2, wherein the plurality of switches are configured to be in the open configuration when the battery system is in a power off mode, a stowage mode, and/or a disconnected mode.

9. The apparatus of example 8, further comprising at least one processor configured to control the plurality of switches individually so that the plurality of sets of one or more electrochemical cells are connected in a commanded configuration, the controlling comprises:
determining a subset of the plurality of switches to be switched from an open configuration to a closed configuration or from a closed configuration to an open configuration; and
controlling the subset of the plurality of switches to alternate between the open configuration and close configuration.

10. The apparatus of example 9, further comprising a pulse width modulation (PWM) circuitry configured to provide PWM signals to the subset of the plurality of switches to control the subset of the plurality of switches to alternate between the open configuration and the closed configuration, the controlling comprises alternating the PWM signals between a logical state and a second logical state to an output of each of the subset of the plurality of switches to also alternate between the first logical state and the second logical stage.

11. The apparatus of example 2, wherein the plurality of switches comprise a plurality of field effect transistors.

12. The apparatus of example 2, further comprising:
at least a first power terminal configured to be electrically coupled to an electrical terminal of a first corresponding pair of the plurality of pairs of electrical terminals, wherein the first power terminal is configured to operate at a first voltage; and
at least a second power terminal configured to be electrically coupled to an electrical terminal of a second corresponding pair of the plurality of pairs of electrical terminals, wherein the second power terminal is configured to operate at a second voltage different from the first voltage.

13. The apparatus of example 12, further comprising:
a first additional switch electrically coupled to the first power terminal and a positive terminal of the first corresponding pair of the plurality of pairs of electrical terminals and configured to connect/disconnect the first power terminal to/from the positive terminal of the first corresponding pair of the plurality of pairs of electrical terminals; and
a second additional switch electrically coupled to the second power terminal and a positive terminal of the second corresponding pair of the plurality of pairs of electrical terminals and configured to connect/disconnect the second power terminal to/from the positive terminal of the second corresponding pair of the plurality of pairs of electrical terminals.

14. The apparatus of example 12, further comprising:
a first additional switch coupled to the first power terminal and a power bus; and
a second additional switch coupled to the second power terminal and the power bus.

15. The apparatus of example 14, further comprising a third power terminal electrically coupled to a second power bus.

16. The apparatus of example 12, further comprising:
a measuring circuitry coupled to the first power terminal or the second power terminal and configured to measure a state at the first power terminal or the second power terminal; and
at least one processor coupled to the measuring circuitry, and configured to:
   control an additional switch to activate the measuring circuitry to measure the state at the first power terminal or the second power terminal; and
   receive the state at the first power terminal or the second power terminal from the measuring circuitry.

17. The apparatus of example 2, further comprising a fault detection circuitry configured to detect at least a faulty switch of the plurality of switches.

18. The apparatus of example 2, further comprising:
a communication interface configured to communicate with the plurality of sets of one or more electrochemical cells; and
at least one processor configured to identify the plurality of sets of one or more electrochemical cells by:
   controlling the plurality of switches to select a pair of the plurality of pairs of electrical terminals;
   changing operating state of a respective set of the plurality of sets of one or more electrochemical cells connected to the selected pair of electrical terminals;
   receiving an acknowledgment signal from the respective set of the plurality of sets of one or more electrochemical cells via the communication interface; and
   associating the respective set of the plurality of sets of one or more electrochemical cells with a location of the selected pair of electrical terminals as a location of the respective set of the plurality of sets of one or more electrochemical cells.

19. The apparatus of example 18, wherein the at least one processor is further configured to identify the respective set of the plurality of sets of one or more electrochemical cells by, additionally receiving one or more battery properties from the respective set of the plurality of sets of one or more electrochemical cells.

20. The apparatus of example 2, further comprising:
a communication interface configured to communicate with the plurality of sets of electrochemical cells and additional plurality of sets of electrochemical cells in one or more additional battery systems each comprising a plurality of sets of electrochemical cells and associated with one or more respective controller circuit boards, wherein the battery system and one or more additional battery systems are connected by one or more bus bars; and
at least one processor configured to pair the plurality of sets of electrochemical cells and the additional plurality of sets of electrochemical cells by:
   controlling the plurality of switches to select a pair of the plurality of pairs of electrical terminals in the plurality of controller circuit boards and the one or more respective controller circuit boards associated with each of the one or more additional battery systems;
   changing operating state of a respective set of the plurality of sets of electrochemical cells connected to the selected pair of electrical terminals and operating state of corresponding sets of electrochemical cells in the one or more additional battery systems;
   receiving signals from the respective set of the plurality of sets of electrochemical cells and one or more corresponding sets of electrochemical cells in the one or more additional battery systems via the communication interface; and
   pairing the respective set of the plurality of sets of electrochemical cells with the one or more corresponding sets of electrochemical cells in the one or more additional battery systems.

21. The apparatus of example 2, further comprising at least one processor configured to perform balancing, by:
determining that the plurality of sets of one or more electrochemical cells include one or more imbalanced sets of one or more electrochemical cells; and
controlling one or more of the plurality of switches to change a connection of the one or more imbalanced sets of one or more electrochemical cells.

22. The apparatus of example 21, wherein changing the connection of the one or more imbalanced sets of one or more electrochemical cells includes connecting the one or more imbalanced sets of one or more electrochemical cells to a charging circuit.

23. The apparatus of example 21, wherein the at least one processor is further configured to:
responsive to determining that the plurality of sets of electrochemical cells include one or more imbalanced sets of electrochemical cells, transmit a notification to a user.

24. A method for controlling a battery system, the method comprising, by at least one processor:
controlling one or more of a plurality of switches on a controller individually to connect one or more of a plurality of pairs of electrical terminals on the controller according to a commanded configuration;
wherein:
   the plurality of pairs of electrical terminals are configured to be electrically connected to a plurality of electrical energy storage devices, wherein the plurality of pairs of electrical terminals include at least a first pair of electrical terminals and a second pair of electrical terminals, wherein each pair of electrical terminals include a positive terminal and a negative terminal; and
   the plurality of switches are configured to be independently controlled between an open configuration and a closed configuration, wherein the plurality of switches include at least:
      at least a first switch disposed along a first electrical path extending between a positive terminal of the first pair of electrical terminals and a positive terminal of the second pair of electrical terminals;
      at least a second switch disposed along a second electrical path extending between a negative terminal of the first pair of electrical terminals and a negative terminal of the second pair of electrical terminals; and
      a third switch electrically coupled to the negative terminal of the first pair of electrical terminals and the positive terminal of the second pair of electrical terminals.

25. The method of example 24, wherein the plurality of electrical energy storage devices comprises a plurality of sets of one or more electrochemical cells.

26. The method of example 25, wherein
the first switch is electrically coupled to a positive terminal of the first pair of electrical terminals and a positive terminal of the second pair of electrical terminals; and
the second switch electrically coupled to a negative terminal of the first pair of electrical terminals and a negative terminal of the second pair of electrical terminals.

27. The method of example 25, wherein:
the first switch is electrically coupled to the positive terminal of the first pair of electrical terminals and a first power bus; and
the second switch is electrically coupled to the negative terminal of the first pair of electrical terminals and a second power bus.

28. The method of example 27, wherein the plurality of switches further includes:
a fourth switch electrically coupled to the positive terminal of the second pair of electrical terminals and the first power bus; and
a fifth switch electrically coupled to the negative terminal of the second pair of electrical terminals and the second power bus.

29. The method of example 25, wherein the command configuration includes at least an isolated connection, a series connection, a parallel connection, and/or a combination of series connections and parallel connections of one or more of the plurality of sets of one or more electrochemical cells.

30. The method of example 25, wherein:
the plurality of switches are configured to be in the open configuration when the battery system is in a power off mode, a stowage mode, and/or a disconnected mode; and
controlling the one or more of the plurality of switches comprises, at a start of the battery system:
   determining the one of more of the plurality of switches to be switched to the closed configuration; and
   controlling the one or more of the plurality of switches to alternate between the open configuration and close configuration.

31. The method of example 30, wherein controlling the one or more of the plurality of switches to alternate between the open configuration and close configuration comprises:

using a pulse width modulation circuitry to provide control signal to the one or more of the plurality of switches, wherein the control signal alternates between a first logical state and a second logical state.

32. The method of example 25, wherein the plurality of switches comprise a plurality of field effect transistors.

33. The method of example 25, further comprising:
connecting a first power terminal to an electrical terminal of a first corresponding pair of the plurality of pairs of electrical terminals to operate at a first voltage; and
connecting a second power terminal to an electrical terminal of a second corresponding pair of the plurality of pairs of electrical terminals to operate at a second voltage different from the first voltage.

34. The method of example 33, wherein:
connecting the first power terminal to an electrical terminal of a first corresponding pair of the plurality of pairs of electrical terminals comprises controlling a first additional switch to connect the first power terminal to a positive terminal of the first corresponding pair of the plurality of pairs of electrical terminals; and
connecting the second power terminal to an electrical terminal of a second corresponding pair of the plurality of pairs of electrical terminals comprises controlling a second additional switch to connect the second power terminal to a positive terminal of the second corresponding pair of the plurality of pairs of electrical terminals.

35. The method of example 33, further comprising:
controlling an additional switch to activate a measuring circuitry to measure a state at the first power terminal or the second power terminal; and
receive the state at the first power terminal or the second power terminal from the measuring circuitry.

36. The method of example 25, further comprising using a fault detection circuitry to detect at least a faulty switch of the plurality of switches.

37. The method of example 25, further comprising identifying the plurality of sets of one or more electrochemical cells by:
controlling the plurality of switches to select a pair of the plurality of pairs of electrical terminals;
changing operating state of a respective set of the plurality of sets of one or more electrochemical cells connected to the selected pair of electrical terminals;
receiving an acknowledgment signal from the respective set of the plurality of sets of one or more electrochemical cells via a communication interface; and
associating the respective set of the plurality of sets of one or more electrochemical cells with a location of the selected pair of electrical terminals as a location of the respective set of the plurality of sets of one or more electrochemical cells.

38. The method of example 37, further comprising identifying the respective set of the plurality of sets of one or more electrochemical cells by additionally receiving one or more battery properties from the respective set of the plurality of sets of one or more electrochemical cells.

39. The method of example 25, further comprising performing balancing, by:
determining that the plurality of sets of one or more electrochemical cells include one or more imbalanced sets of one or more electrochemical cells; and
controlling one or more of the plurality of switches to change a connection of the one or more imbalanced sets of one or more electrochemical cells.

40. The method of example 39, wherein changing the connection of the one or more imbalanced sets of one or more electrochemical cells includes connecting the one or more imbalanced sets of one or more electrochemical cells to a charging circuit.

41. An apparatus for controlling a battery system, the apparatus comprising:
a plurality of controller circuit boards configured to connect with each other, wherein each of the plurality of controller circuit boards comprises:
   a plurality of pairs of electrical terminals configured to be electrically connected to a plurality of electrical energy storage devices of the battery system;
   a plurality of switches electrically coupled to the plurality of pairs of electrical terminals, wherein the plurality of switches are configured to control an electrical configuration of the plurality of electrical energy storage devices; and
   a plurality of pins coupled to the plurality of switches to provide control signals to the plurality of switches, wherein the plurality of pins of the plurality of controller circuit boards are configured to be commonly connected.

42. The apparatus of example 41, wherein the plurality of electrical energy storage devices comprises a plurality of sets of one or more electrochemical cells.

43. The apparatus of example 42, further comprising at least one processor configured to control the plurality of switches of the plurality of controller circuit boards via the commonly connected plurality of pins of the plurality of controller circuit boards.

44. The apparatus of example 43, wherein the at least one processor is installed on a first controller circuit board of the plurality of controller circuit boards and electrically coupled to the commonly connected plurality of pins of the plurality of controller circuit boards.

45. The apparatus of example 43, wherein the plurality of switches are configured to be in the open configuration when the battery system is in a power off mode, a stowage mode, and/or a disconnected mode.

46. The apparatus of example 45, wherein the at least one processor is configured to control the plurality of switches individually so that the plurality of sets of one or more electrochemical cells are connected in a commanded configuration, the controlling comprises:
determining a subset of the plurality of switches of the plurality of controller circuit boards to be switched to the closed configuration; and
controlling the subset of the plurality of switches to alternate between the open configuration and close configuration.

47. The apparatus of example 46, further comprising a pulse width modulation (PWM) circuitry configured to provide PWM signals to the subset of the plurality of switches to control the subset of the plurality of switches to alternate between the open configuration and close configuration, the controlling comprises alternating the PWM signals between a logical state and a second logical state to an output of each of the subset of the plurality of switches to also alternate between the first logical state and the second logical stage.

48. The apparatus of example 42, wherein the plurality of switches in the plurality of controller circuit boards comprise a plurality of field effect transistors.

49. The apparatus of example 42, further comprising a fault detection circuitry configured to detect at least a faulty switch of the plurality of switches.

50. The apparatus of example 42, further comprising:
a measuring circuitry coupled to a power terminal and configured to measure a state at the power terminal; and
at least one processor coupled to the measuring circuitry, and configured to:
   control an additional switch to activate the measuring circuitry to measure the state at the power terminal; and
   receive the state at the power terminal from the measuring circuitry.

51. The apparatus of example 42, wherein the plurality of pairs of electrical terminals of the plurality of controller circuit boards are configured to be commonly connected and configured to be connected to one or more groups of battery packs each comprising a plurality of sets of one or more electrochemical cells;
whereby, when the one or more groups of battery packs are connected to the commonly connected plurality of pairs of electrical terminals, an overall current drawn by a load from the one or more groups of battery packs is distributed among the plurality of controller circuit boards such that a current drawn in each individual controller circuit board of the plurality of controller circuit boards is below a current rating of the individual controller circuit board.

52. The apparatus of example 51, further comprising:
a communication interface configured to communicate with the one or more groups of battery packs; and
at least one processor configured to identify the plurality of sets of one or more electrochemical cells in the one or more groups of the plurality of battery packs by:
   controlling the plurality of switches in the plurality of controller circuit boards to select a commonly connected pair of the electrical terminals for each of the plurality of controller circuit boards;
   changing an operating state of corresponding sets of the plurality of sets of one or more electrochemical cells in the one or more groups of battery packs connected to the selected commonly connected pair of electrical terminals;
   receiving an acknowledgment signal from the corresponding sets of the plurality of sets of one or more electrochemical cells in the one or more groups of battery packs; and
   associating the corresponding sets of the plurality of sets of one or more electrochemical cells in the one or more groups of the battery packs with a location of the selected commonly connected pair of electrical terminals as a location of the corresponding sets of the plurality of sets of one or more electrochemical cells in the one or more groups of the battery packs.

53. The apparatus of example 52, wherein the at least one processor is further configured to identify the corresponding sets of the plurality of sets of one or more electrochemical cells in the one or more groups of battery packs by, additionally receiving one or more battery properties from the corresponding sets of the plurality of sets of one or more electrochemical cells.

54. The apparatus of example 51, wherein one or more of the plurality of controller circuit boards are configured to be connected to one or more external controller circuit boards via the commonly connected plurality of pins of the one or more of the plurality of controller circuit boards, wherein the one or more external controller circuit boards are associated with one or more battery systems external to the battery system and connecting to the battery system by one or more bus bars.

55. The apparatus of example 54, further comprising at least one processor configured to
control a plurality of switches of the one or more external controller circuit boards via the commonly connected plurality of pins of the plurality of controller circuit boards.

56. The apparatus of example 55, further comprising:
a communication interface configured to communicate with the one or more groups of battery packs in the battery system and additional one or more groups of battery packs in the one or more battery systems external to the battery system;
wherein the at least processor is further configured to receive signals from the one or more external controller circuits boards via the communication interface.

57. The apparatus of example 56, wherein the communication interface is operable in a wireless mesh network.

58. The apparatus of example 56, wherein the at least one processor is further configured to identify additional plurality of sets of electrochemical cells in the one or more battery systems external to the battery system, by:
changing operating state of one or more corresponding sets of the plurality of sets of electrochemical cells in the one or more battery systems external to the battery system; and
receiving signals from the one or more corresponding sets of the plurality of sets of electrochemical cells in the one or more additional battery systems via the communication interface; and
identifying the one or more corresponding sets of the plurality of sets of electrochemical cells in the one or more additional battery systems.

59. The apparatus of example 51, further comprising at least one processor configured to perform balancing, by:
determining that the plurality of sets of one or more electrochemical cells in the one or more groups of battery packs include one or more imbalanced sets of one or more electrochemical cells; and
controlling one or more of the plurality of switches in the plurality of controller circuit boards to change connection of the one or more imbalanced sets of one or more electrochemical cells.

60. The apparatus of example 59, wherein changing the connection of the one or more imbalanced sets of one or more electrochemical cells comprises connecting the one or more imbalanced sets of one or more electrochemical cells to a charging circuit.

61. The apparatus of example 60, further comprising at least a first power terminal configured to provide power to a load at a first voltage and at least a second power terminal configured to provide power to a load at a second voltage different from the first voltage; wherein the at least one processor is further configured to perform balancing, additionally by:
coupling the first power terminal to the one or more imbalanced sets of one or more electrochemical cells in the one or more groups of battery packs to enable equalization of voltages thereof using a charging source applied to the first terminal;
wherein one or more of other sets of one or more electrochemical cells in the one or more groups of battery packs are connected a load via the second power terminal at least in parallel with the one or more imbalanced sets of one or more electrochemical cells in the one or more groups of battery packs being charged.

62. The apparatus of example 42, wherein the plurality of controller circuit boards are stacked.

63. The apparatus of example 62, wherein a plurality of conductive bushings are disposed between adjacent controller circuit boards of the plurality of controller circuit boards and configured to connect corresponding pairs of electrical terminals of the plurality of pairs of electrical terminals of the adjacent controller circuit boards.

64. A method for controlling a battery system, the method comprising, by at least one processor:
controlling, with common control signals, a respective plurality of switches on each controller circuit board of a plurality of controller circuit boards connected with each other to connect one or more of a respective plurality of pairs of electrical terminals on the controller circuit board according to a commanded configuration;
wherein, for each controller circuit board of the plurality of controller circuit boards:
   the plurality of pairs of electrical terminals are configured to be electrically connected to a plurality of electrical energy storage devices of the battery system; and
   the plurality of switches are electrically coupled to the plurality of pairs of electrical terminals, wherein the plurality of switches are configured to control an electrical configuration of the plurality of electrical energy storage devices; and
wherein:
   the respective plurality of pairs of electrical terminals on each of the plurality of controller circuit boards are commonly connected; and
   the respective plurality of switches on each of the plurality of controller circuit boards are commonly connected.

65. The method of example 64, wherein the plurality of electrical energy storage devices comprises a plurality of sets of one or more electrochemical cells.

66. The method of example 65, wherein:
each controller circuit board of the plurality of controller circuit boards comprises a plurality of pins coupled to the plurality of switches to provide control signals to the plurality of switches, wherein the plurality of pins of the plurality of controller circuit boards are commonly connected; and
the common control signals are provided to the respective plurality of switches on each controller circuit board of a plurality of controller circuit boards via respective plurality of pins of the controller circuit board.

67. The method of example 65, wherein the at least one processor is installed on a first controller circuit board of the plurality of controller circuit boards and electrically coupled to the commonly connected plurality of pins of the plurality of controller circuit boards.

68. The method of example 65, wherein:
the respective plurality of switches of the plurality of controller circuit board are configured to be in the open configuration when the battery system is in a power off mode, a stowage mode, and/or a disconnected mode; and
controlling the respective plurality of switches on each controller circuit board of the plurality of controller circuit boards comprises, at a start of the battery system:
   determining a subset of the plurality of switches of the plurality of controller circuit boards to be switched to the closed configuration; and
   controlling the subset of the plurality of switches to alternate between the open configuration and close configuration.

69. The method of example 68, wherein controlling the subset of the plurality of switches to alternate between the open configuration and close configuration comprises:
using a pulse width modulation circuitry to provide control signals to the subset of the plurality of switches.

70. The method of example 65, wherein the plurality of switches for each of the plurality of controller circuit boards comprise a plurality of field effect transistors.

71. The method of example 65, further comprising using a fault detection circuitry to detect at least a faulty switch of the plurality of switches of the plurality of controller circuit boards.

72. The method of example 65, further comprising:
controlling an additional switch to activate a measuring circuitry to measure a state at a power terminal; and
receiving the state at the power terminal from the measuring circuitry.

73. The method of example 65, wherein the respective plurality of pairs of electrical terminals of each of the plurality of controller circuit boards are configured to be connected to one or more groups of battery packs each comprising a plurality of sets of one or more electrochemical cells;
whereby, when the one or more groups of battery packs are connected to the commonly connected plurality of pairs of electrical terminals, an overall current drawn by a load from the one or more groups of battery packs is distributed among the plurality of controller circuit boards such that a current drawn in each individual controller circuit board of the plurality of controller circuit boards is below a current rating of the individual controller circuit board.

74. The method of example 73, further comprising identifying the plurality of sets of one or more electrochemical cells in the one or more groups of the plurality of battery packs by:
controlling the plurality of switches in the plurality of controller circuit boards to select a commonly connected pair of the electrical terminals for each of the plurality of controller circuit boards;
changing operating state of corresponding sets of the plurality of sets of one or more electrochemical cells in the one or more groups of battery packs connected to the selected commonly connected pair of electrical terminals;
receiving an acknowledgment signal from the corresponding sets of the plurality of sets of one or more electrochemical cells in the one or more groups of battery packs; and
associating the corresponding sets of the plurality of sets of one or more electrochemical cells in the one or more groups of the battery packs with a location of the selected commonly connected pair of electrical terminals as a location of the corresponding sets of the plurality of sets of one or more electrochemical cells in the one or more groups of the battery packs.

75. The method of example 74, further comprising identifying the corresponding sets of the plurality of sets of one or more electrochemical cells in the one or more groups of battery packs by, additionally receiving one or more battery properties from the corresponding sets of the plurality of sets of one or more electrochemical cells.

76. The method of example 73, further comprising performing balancing, by:
determining that the plurality of sets of one or more electrochemical cells in the one or more groups of battery packs include one or more imbalanced sets of one or more electrochemical cells; and
controlling one or more of the plurality of switches in the plurality of controller circuit boards to change connection of the one or more imbalanced sets of one or more electrochemical cells.

77. The method of example 76, wherein changing the connection of the one or more imbalanced sets of one or more electrochemical cells comprises connecting the one or more imbalanced sets of one or more electrochemical cells to a charging circuit.

78. The method of example 77, further comprising:
providing power to a load at a first power terminal a first voltage; and
providing power to a load at a second power terminal at a second voltage different from the first voltage;
wherein performing the balancing further comprises:
   coupling the first power terminal to the one or more imbalanced sets of one or more electrochemical cells in the one or more groups of battery packs to enable equalization of voltages thereof using a charging source applied to the first terminal; and
wherein one or more of other sets of one or more electrochemical cells in the one or more groups of battery packs are connected a load via the second power terminal at least in parallel with the one or more imbalanced sets of one or more electrochemical cells in the one or more groups of battery packs being charged.

79. The method of example 65, wherein the plurality of controller circuit boards are stacked.

80. The method of example 79, wherein a plurality of conductive bushings are disposed between adjacent controller circuit boards of the plurality of controller circuit boards and configured to connect corresponding pairs of electrical terminals of the plurality of pairs of electrical terminals of the adjacent controller circuit boards.

Having thus described several aspects of at least one embodiment of this invention, it is to be appreciated that various alterations, modifications, and improvements will readily occur to those skilled in the art.

Such alterations, modifications, and improvements are intended to be part of this disclosure, and are intended to be within the spirit and scope of the invention. Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

1. An apparatus for controlling a battery system, the apparatus comprising:
a plurality of pairs of electrical terminals configured to be electrically connected to a plurality of electrical energy storage devices, wherein the plurality of pairs of electrical terminals include at least a first pair of electrical terminals and a second pair of electrical terminals, wherein each pair of electrical terminals include a positive terminal and a negative terminal; and
a plurality of switches configured to be independently controlled between an open configuration and a closed configuration, wherein the plurality of switches include at least:
at least a first switch disposed along a first electrical path extending between a positive terminal of the first pair of electrical terminals and a positive terminal of the second pair of electrical terminals;
at least a second switch disposed along a second electrical path extending between a negative terminal of the first pair of electrical terminals and a negative terminal of the second pair of electrical terminals; and
a third switch electrically coupled to the negative terminal of the first pair of electrical terminals and the positive terminal of the second pair of electrical terminals.

2. The apparatus of claim 1, wherein the plurality of electrical energy storage devices comprises a plurality of sets of one or more electrochemical cells.

3. The apparatus of claim 2, wherein:
the first switch is electrically coupled to a positive terminal of the first pair of electrical terminals and a positive terminal of the second pair of electrical terminals; and
the second switch electrically coupled to a negative terminal of the first pair of electrical terminals and a negative terminal of the second pair of electrical terminals.

4. The apparatus of claim 2, wherein:
the first switch is electrically coupled to the positive terminal of the first pair of electrical terminals and a first power bus; and
the second switch is electrically coupled to the negative terminal of the first pair of electrical terminals and a second power bus.

5. The apparatus of claim 4, wherein the plurality of switches further includes:
a fourth switch electrically coupled to the positive terminal of the second pair of electrical terminals and the first power bus; and
a fifth switch electrically coupled to the negative terminal of the second pair of electrical terminals and the second power bus.

6. The apparatus of claim 2, further comprising at least one processor configured to control the plurality of switches individually so that the plurality of sets of one or more electrochemical cells are connected in a commanded configuration.

7. The apparatus of claim 6, wherein the commanded configuration includes at least an isolated connection, a series connection, a parallel connection, and/or a combination of series connections and parallel connections of one or more of the plurality of sets of one or more electrochemical cells.

8. The apparatus of claim 2, wherein the plurality of switches are configured to be in the open configuration when the battery system is in a power off mode, a stowage mode, and/or a disconnected mode.

9. The apparatus of claim 8, further comprising at least one processor configured to control the plurality of switches individually so that the plurality of sets of one or more electrochemical cells are connected in a commanded configuration, the controlling comprises:
determining a subset of the plurality of switches to be switched from an open configuration to a closed configuration or from a closed configuration to an open configuration; and
controlling the subset of the plurality of switches to alternate between the open configuration and close configuration.

10. The apparatus of claim 9, further comprising a pulse width modulation (PWM) circuitry configured to provide PWM signals to the subset of the plurality of switches to control the subset of the plurality of switches to alternate between the open configuration and the closed configuration, the controlling comprises alternating the PWM signals between a logical state and a second logical state to an output of each of the subset of the plurality of switches to also alternate between the first logical state and the second logical stage.

11. The apparatus of claim 2, wherein the plurality of switches comprise a plurality of field effect transistors.

12. The apparatus of claim 2, further comprising:
at least a first power terminal configured to be electrically coupled to an electrical terminal of a first corresponding pair of the plurality of pairs of electrical terminals, wherein the first power terminal is configured to operate at a first voltage; and
at least a second power terminal configured to be electrically coupled to an electrical terminal of a second corresponding pair of the plurality of pairs of electrical terminals, wherein the second power terminal is configured to operate at a second voltage different from the first voltage.

13. The apparatus of claim 12, further comprising:
a first additional switch electrically coupled to the first power terminal and a positive terminal of the first corresponding pair of the plurality of pairs of electrical terminals and configured to connect/disconnect the first power terminal to/from the positive terminal of the first corresponding pair of the plurality of pairs of electrical terminals; and
a second additional switch electrically coupled to the second power terminal and a positive terminal of the second corresponding pair of the plurality of pairs of electrical terminals and configured to connect/disconnect the second power terminal to/from the positive terminal of the second corresponding pair of the plurality of pairs of electrical terminals.

14. The apparatus of claim 12, further comprising:
a first additional switch coupled to the first power terminal and a power bus; and
a second additional switch coupled to the second power terminal and the power bus.

15. The apparatus of claim 14, further comprising a third power terminal electrically coupled to a second power bus.

16. The apparatus of claim 12, further comprising:
a measuring circuitry coupled to the first power terminal or the second power terminal and configured to measure a state at the first power terminal or the second power terminal; and
at least one processor coupled to the measuring circuitry, and configured to:
control an additional switch to activate the measuring circuitry to measure the state at the first power terminal or the second power terminal; and
receive the state at the first power terminal or the second power terminal from the measuring circuitry.

17. The apparatus of claim 2, further comprising a fault detection circuitry configured to detect at least a faulty switch of the plurality of switches.

18. The apparatus of claim 2, further comprising:
a communication interface configured to communicate with the plurality of sets of one or more electrochemical cells; and
at least one processor configured to identify the plurality of sets of one or more electrochemical cells by:
controlling the plurality of switches to select a pair of the plurality of pairs of electrical terminals;
changing operating state of a respective set of the plurality of sets of one or more electrochemical cells connected to the selected pair of electrical terminals;
receiving an acknowledgment signal from the respective set of the plurality of sets of one or more electrochemical cells via the communication interface; and
associating the respective set of the plurality of sets of one or more electrochemical cells with a location of the selected pair of electrical terminals as a location of the respective set of the plurality of sets of one or more electrochemical cells.

19. The apparatus of claim 18, wherein the at least one processor is further configured to identify the respective set of the plurality of sets of one or more electrochemical cells by, additionally receiving one or more battery properties from the respective set of the plurality of sets of one or more electrochemical cells.

20. The apparatus of claim 2, further comprising:
a communication interface configured to communicate with the plurality of sets of electrochemical cells and additional plurality of sets of electrochemical cells in one or more additional battery systems each comprising a plurality of sets of electrochemical cells and associated with one or more respective controller circuit boards, wherein the battery system and one or more additional battery systems are connected by one or more bus bars; and
at least one processor configured to pair the plurality of sets of electrochemical cells and the additional plurality of sets of electrochemical cells by:
controlling the plurality of switches to select a pair of the plurality of pairs of electrical terminals in the plurality of controller circuit boards and the one or more respective controller circuit boards associated with each of the one or more additional battery systems;
changing operating state of a respective set of the plurality of sets of electrochemical cells connected to the selected pair of electrical terminals and operating state of corresponding sets of electrochemical cells in the one or more additional battery systems;
receiving signals from the respective set of the plurality of sets of electrochemical cells and one or more corresponding sets of electrochemical cells in the one or more additional battery systems via the communication interface; and
pairing the respective set of the plurality of sets of electrochemical cells with the one or more corresponding sets of electrochemical cells in the one or more additional battery systems.

21. The apparatus of claim 2, further comprising at least one processor configured to perform balancing, by:
determining that the plurality of sets of one or more electrochemical cells include one or more imbalanced sets of one or more electrochemical cells; and
controlling one or more of the plurality of switches to change a connection of the one or more imbalanced sets of one or more electrochemical cells.

22. The apparatus of claim 21, wherein changing the connection of the one or more imbalanced sets of one or more electrochemical cells includes connecting the one or more imbalanced sets of one or more electrochemical cells to a charging circuit.

23. The apparatus of claim 21, wherein the at least one processor is further configured to:
responsive to determining that the plurality of sets of electrochemical cells include one or more imbalanced sets of electrochemical cells, transmit a notification to a user.

24. A method for controlling a battery system, the method comprising, by at least one processor:
controlling one or more of a plurality of switches on a controller individually to connect one or more of a plurality of pairs of electrical terminals on the controller according to a commanded configuration;
wherein:
the plurality of pairs of electrical terminals are configured to be electrically connected to a plurality of electrical energy storage devices, wherein the plurality of pairs of electrical terminals include at least a first pair of electrical terminals and a second pair of electrical terminals, wherein each pair of electrical terminals include a positive terminal and a negative terminal; and
the plurality of switches are configured to be independently controlled between an open configuration and a closed configuration, wherein the plurality of switches include at least:
at least a first switch disposed along a first electrical path extending between a positive terminal of the first pair of electrical terminals and a positive terminal of the second pair of electrical terminals;
at least a second switch disposed along a second electrical path extending between a negative terminal of the first pair of electrical terminals and a negative terminal of the second pair of electrical terminals; and
a third switch electrically coupled to the negative terminal of the first pair of electrical terminals and the positive terminal of the second pair of electrical terminals.

25. The method of claim 24, wherein the plurality of electrical energy storage devices comprises a plurality of sets of one or more electrochemical cells.

26. The method of claim 25, wherein
the first switch is electrically coupled to a positive terminal of the first pair of electrical terminals and a positive terminal of the second pair of electrical terminals; and
the second switch electrically coupled to a negative terminal of the first pair of electrical terminals and a negative terminal of the second pair of electrical terminals.

27. The method of claim 25, wherein:
the first switch is electrically coupled to the positive terminal of the first pair of electrical terminals and a first power bus; and
the second switch is electrically coupled to the negative terminal of the first pair of electrical terminals and a second power bus.

28. The method of claim 27, wherein the plurality of switches further includes:
a fourth switch electrically coupled to the positive terminal of the second pair of electrical terminals and the first power bus; and
a fifth switch electrically coupled to the negative terminal of the second pair of electrical terminals and the second power bus.

29. The method of claim 25, wherein the command configuration includes at least an isolated connection, a series connection, a parallel connection, and/or a combination of series connections and parallel connections of one or more of the plurality of sets of one or more electrochemical cells.

30. The method of claim 25, wherein:
the plurality of switches are configured to be in the open configuration when the battery system is in a power off mode, a stowage mode, and/or a disconnected mode; and
controlling the one or more of the plurality of switches comprises, at a start of the battery system:
determining the one of more of the plurality of switches to be switched to the closed configuration; and
controlling the one or more of the plurality of switches to alternate between the open configuration and close configuration.

31. The method of claim 30, wherein controlling the one or more of the plurality of switches to alternate between the open configuration and close configuration comprises:
using a pulse width modulation circuitry to provide control signal to the one or more of the plurality of switches, wherein the control signal alternates between a first logical state and a second logical state.

32. The method of claim 25, wherein the plurality of switches comprise a plurality of field effect transistors.

33. The method of claim 25, further comprising:
connecting a first power terminal to an electrical terminal of a first corresponding pair of the plurality of pairs of electrical terminals to operate at a first voltage; and
connecting a second power terminal to an electrical terminal of a second corresponding pair of the plurality of pairs of electrical terminals to operate at a second voltage different from the first voltage.

34. The method of claim 33, wherein:
connecting the first power terminal to an electrical terminal of a first corresponding pair of the plurality of pairs of electrical terminals comprises controlling a first additional switch to connect the first power terminal to a positive terminal of the first corresponding pair of the plurality of pairs of electrical terminals; and
connecting the second power terminal to an electrical terminal of a second corresponding pair of the plurality of pairs of electrical terminals comprises controlling a second additional switch to connect the second power terminal to a positive terminal of the second corresponding pair of the plurality of pairs of electrical terminals.

35. The method of claim 33, further comprising:
controlling an additional switch to activate a measuring circuitry to measure a state at the first power terminal or the second power terminal; and
receive the state at the first power terminal or the second power terminal from the measuring circuitry.

36. The method of claim 25, further comprising using a fault detection circuitry to detect at least a faulty switch of the plurality of switches.

37. The method of claim 25, further comprising identifying the plurality of sets of one or more electrochemical cells by:
controlling the plurality of switches to select a pair of the plurality of pairs of electrical terminals;
changing operating state of a respective set of the plurality of sets of one or more electrochemical cells connected to the selected pair of electrical terminals;
receiving an acknowledgment signal from the respective set of the plurality of sets of one or more electrochemical cells via a communication interface; and
associating the respective set of the plurality of sets of one or more electrochemical cells with a location of the selected pair of electrical terminals as a location of the respective set of the plurality of sets of one or more electrochemical cells.

38. The method of claim 37, further comprising identifying the respective set of the plurality of sets of one or more electrochemical cells by additionally receiving one or more battery properties from the respective set of the plurality of sets of one or more electrochemical cells.

39. The method of claim 25, further comprising performing balancing, by:
determining that the plurality of sets of one or more electrochemical cells include one or more imbalanced sets of one or more electrochemical cells; and
controlling one or more of the plurality of switches to change a connection of the one or more imbalanced sets of one or more electrochemical cells.

40. The method of claim 39, wherein changing the connection of the one or more imbalanced sets of one or more electrochemical cells includes connecting the one or more imbalanced sets of one or more electrochemical cells to a charging circuit.

41. An apparatus for controlling a battery system, the apparatus comprising:
a plurality of controller circuit boards configured to connect with each other, wherein each of the plurality of controller circuit boards comprises:
a plurality of pairs of electrical terminals configured to be electrically connected to a plurality of electrical energy storage devices of the battery system;
a plurality of switches electrically coupled to the plurality of pairs of electrical terminals, wherein the plurality of switches are configured to control an electrical configuration of the plurality of electrical energy storage devices; and
a plurality of pins coupled to the plurality of switches to provide control signals to the plurality of switches, wherein the plurality of pins of the plurality of controller circuit boards are configured to be commonly connected.

42.-63. (canceled)

64. A method for controlling a battery system, the method comprising, by at least one processor:
controlling, with common control signals, a respective plurality of switches on each controller circuit board of a plurality of controller circuit boards connected with each other to connect one or more of a respective plurality of pairs of electrical terminals on the controller circuit board according to a commanded configuration;
wherein, for each controller circuit board of the plurality of controller circuit boards:
the plurality of pairs of electrical terminals are configured to be electrically connected to a plurality of electrical energy storage devices of the battery system; and
the plurality of switches are electrically coupled to the plurality of pairs of electrical terminals, wherein the plurality of switches are configured to control an electrical configuration of the plurality of electrical energy storage devices; and
wherein:
the respective plurality of pairs of electrical terminals on each of the plurality of controller circuit boards are commonly connected; and
the respective plurality of switches on each of the plurality of controller circuit boards are commonly connected.

65.-80. (canceled)
